(19) United States
(12) Patent Application Publication
(10) Pub. No.: US 2026/0059950 A1
(43) Pub. Date: Feb. 26, 2026

(54) DISPLAY PANEL, METHOD FOR PREPARING THE SAME, AND DISPLAY APPARATUS

(71) Applicant: WUHAN TIANMA MICROELECTRONICS CO., LTD., Wuhan (CN)

(72) Inventors: Qiyong KE, Wuhan (CN); Shuangli ZHU, Wuhan (CN); Xiaojin ZHOU, Wuhan (CN); Zhenjun YANG, Wuhan (CN)

(21) Appl. No.: 19/375,713

(22) Filed: Oct. 31, 2025

(30) Foreign Application Priority Data
Jul. 16, 2025 (CN) 202510983509.0

(51) Int. Cl. H10K 59/122; H10K 59/12; H10K 59/126; H10K 102/00

(52) U.S. Cl. CPC H10K 59/122; H10K 59/1201; H10K 59/126; H10K 2102/351

(57) ABSTRACT

A display panel, a method for preparing the display panel and a display apparatus are provided. The display panel includes a first pixel definition layer including a first pixel opening and a first opening, a second pixel definition layer including a second pixel opening and a second opening, and a third pixel definition layer. The first opening penetrates the first pixel definition layer, and at least partially surrounds the first pixel opening. The second opening penetrates the second pixel definition layer, and at least partially surrounds the second pixel opening. Along a direction perpendicular to a plane of the substrate, the second opening at least partially overlaps the first opening. The third pixel definition layer at least partially overlaps the first opening. At least one of first pixel definition layer and second pixel definition layer includes a light-shielding material.

### CROSS-REFERENCE TO RELATED APPLICATION

The present application claims priority to Chinese Patent Application No. 202510983509.0, filed on Jul. 16, 2025, the content of which is incorporated herein by reference in its entirety.

### TECHNICAL FIELD

The present disclosure relates to the field of display technologies, and in particular, to a display panel, a method for preparing the display panel, and a display apparatus.

### BACKGROUND

Organic Light-Emitting Diodes (OLED) have the advantages such as self-luminous, no backlight source, wide color gamut, high contrast ratio, thinness, wide viewing angle, and fast response speed. As a current-type light-emitting device, OLED display panels have been increasingly applied in high-performance display.

At present, the performance of OLED display panels still needs to be improved.

### SUMMARY

In an aspect, the present disclosure provides a display panel. The display panel includes: a substrate; a first electrode located on a side of the substrate; a first pixel definition layer located on a side of the first electrode away from the substrate; a second pixel definition layer located on a side of the first pixel definition layer away from the substrate; and a third pixel definition layer at least partially overlapping the first opening in the direction perpendicular to the plane of the substrate. The first pixel definition layer includes a first pixel opening and a first opening; the first pixel opening exposes at least part of the first electrode. The first opening penetrates the first pixel definition layer, and at least partially surrounds the first pixel opening. The second pixel definition layer includes a second pixel opening and a second opening. The second pixel opening penetrates the second pixel definition layer, and exposes at least part of the first electrode. The second opening penetrates the second pixel definition layer. The second opening at least partially surrounds the second pixel opening. The second opening at least partially overlaps the first opening in a direction perpendicular to a plane of the substrate. At least one of the first pixel definition layer and the second pixel definition layer includes a light-shielding material.

In another aspect, the present disclosure provides a method for preparing a display panel. The method includes: providing a substrate; forming a first electrode on a side of the substrate; forming a first initial pixel definition layer on a side of the first electrode away from the substrate; forming a first pixel opening and a first opening in the first initial pixel definition layer through a first full-grayscale mask plate to obtain a first pixel definition layer including the first pixel opening and the first opening, the first pixel opening exposes at least part of the first electrode, the first opening penetrates the first pixel definition layer, and the first opening at least partially surrounds the first pixel opening; forming a second initial pixel definition layer on a side of the first pixel definition layer away from the substrate; and forming a second pixel opening and a second opening in the second initial pixel definition layer through a second full-grayscale mask plate, to obtain a second pixel definition layer including the second pixel opening and the second opening, the second pixel opening exposes at least part of the first electrode, the second opening penetrates the second pixel definition layer, the second opening at least partially surrounds the second pixel opening, and the second opening at least partially overlaps the first opening in a direction perpendicular to a plane of the substrate; and forming a third pixel definition layer, the third pixel definition layer at least partially overlaps the first opening along the direction perpendicular to the plane of the substrate. At least one of the first pixel definition layer and the second pixel definition layer includes a light-shielding material.

In another aspect, the present disclosure provides a display apparatus. The display apparatus includes a display panel. The display panel includes: a substrate; a first electrode located on a side of the substrate; a first pixel definition layer located on a side of the first electrode away from the substrate; a second pixel definition layer located on a side of the first pixel definition layer away from the substrate; and a third pixel definition layer at least partially overlapping the first opening in the direction perpendicular to the plane of the substrate. The first pixel definition layer includes a first pixel opening and a first opening; the first pixel opening exposes at least part of the first electrode. The first opening penetrates the first pixel definition layer, and at least partially surrounds the first pixel opening. The second pixel definition layer includes a second pixel opening and a second opening. The second pixel opening penetrates the second pixel definition layer, and exposes at least part of the first electrode. The second opening penetrates the second pixel definition layer. The second opening at least partially surrounds the second pixel opening. The second opening at least partially overlaps the first opening in a direction perpendicular to a plane of the substrate. At least one of the first pixel definition layer and the second pixel definition layer includes a light-shielding material.

### BRIEF DESCRIPTION OF DRAWINGS

In order to illustrate the technical solutions in the embodiments of the present disclosure more clearly, the drawings, which are intended to be used in the description of the embodiments, are briefly described as below. Other drawings described below are merely some embodiments of the present disclosure, and other drawings may be obtained by those skilled in the art according to these drawings.

FIG. 1 is an enlarged schematic diagram of a region where four sub-pixels are located in a display panel according to some embodiments of the present disclosure;

FIG. 2 is a cross-sectional view along line BB′ shown in FIG. 1 according to some embodiments of the present disclosure;

FIG. 3 is a top view of a first pixel definition layer shown in FIG. 1 according to some embodiments of the present disclosure;

FIG. 4 is a top view of a second pixel definition layer shown in FIG. 1 according to some embodiments of the present disclosure;

FIG. 5 is a top view of a third pixel definition layer shown in FIG. 1 according to some embodiments of the present disclosure;

FIG. 6 is a cross-sectional view of a display panel according to some embodiments of the present disclosure;

FIG. 7 is a cross-sectional view of a display panel according to some embodiments of the present disclosure;

FIG. 8 is a cross-sectional view of a display panel according to some embodiments of the present disclosure;

FIG. 9 is a schematic flowchart of a method for preparing a display panel according to some embodiments of the present disclosure;

FIG. 10 is a schematic diagram of a method for preparing a third pixel definition layer according to some embodiments of the present disclosure;

FIG. 11 is a schematic flowchart of another method for preparing a third pixel definition layer according to some embodiments of the present disclosure;

FIG. 12 is a schematic flowchart of a method for preparing a display panel according to some embodiments of the present disclosure;

FIG. 13 is a schematic flowchart of a method for preparing a display panel according to some embodiments of the present disclosure;

FIG. 14 is a schematic flowchart of a method for preparing a display panel according to some embodiments of the present disclosure;

FIG. 15 is an enlarged schematic diagram of a region where four sub-pixels are located in a display panel according to some embodiments of the present disclosure;

FIG. 16 is a top view of a first pixel definition layer shown in FIG. 15 according to some embodiments of the present disclosure;

FIG. 17 is a top view of a second pixel definition layer shown in FIG. 15 according to some embodiments of the present disclosure;

FIG. 18 is a cross-sectional view along line BB′ shown in FIG. 15 according to some embodiments of the present disclosure;

FIG. 19 is an enlarged schematic diagram of a region where four sub-pixels are located in a display panel according to some embodiments of the present disclosure;

FIG. 20 is a top view of a first pixel definition layer shown in FIG. 19 according to some embodiments of the present disclosure;

FIG. 21 is a top view of a second pixel definition layer shown in FIG. 19 according to some embodiments of the present disclosure;

FIG. 22 is a cross-sectional view along line BB′ shown in FIG. 19 according to some embodiments of the present disclosure;

FIG. 23 is a cross-sectional view of a display panel according to some embodiments of the present disclosure;

FIG. 24 is a schematic flowchart of a method for preparing a display panel according to some embodiments of the present disclosure;

FIG. 25 is a schematic flowchart of a method for preparing a display panel according to some embodiments of the present disclosure;

FIG. 26 is a schematic diagram of a method for preparing a second pixel definition layer according to some embodiments of the present disclosure;

FIG. 27 is a schematic diagram of another method for preparing a second pixel definition layer according to some embodiments of the present disclosure; and

FIG. 28 is a schematic diagram of a display apparatus according to some embodiments of the present disclosure.

### DESCRIPTION OF EMBODIMENTS

In order to better understand technical solutions of the present disclosure, the embodiments of the present disclosure are described in detail with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

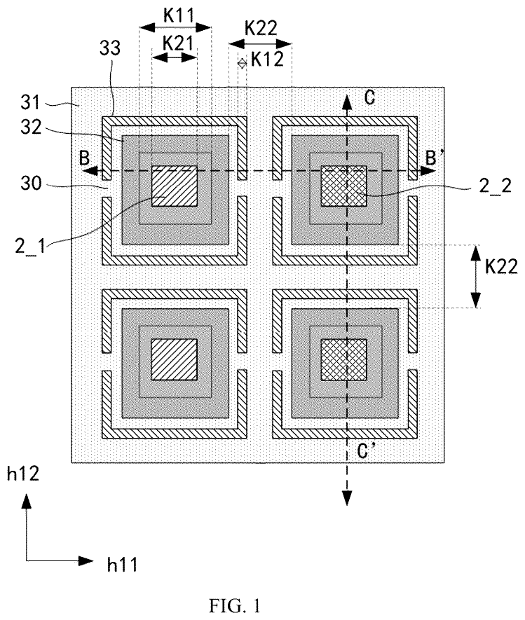

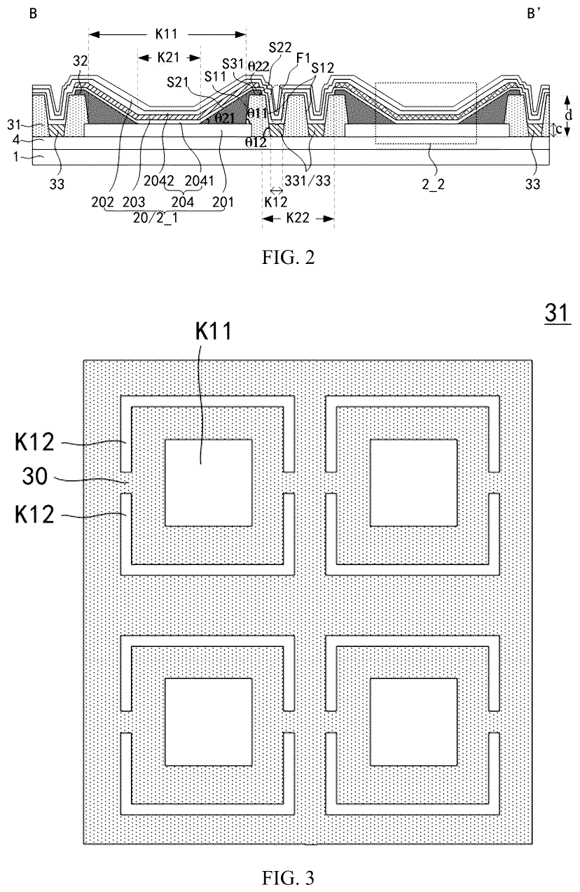

The present disclosure provides a display panel. The display panel includes a plurality of sub-pixels. FIG. 1 is an enlarged schematic diagram of a region where four sub-pixels are located in a display panel according to some embodiments of the present disclosure; and FIG. 2 is a cross-sectional view along line BB′ shown in FIG. 1 according to some embodiments of the present disclosure. As shown in FIG. 1 and FIG. 2, the display panel includes a substrate 1 and a plurality of sub-pixels 2 formed on a side of the substrate 1. In some embodiments of the present disclosure, the plurality of sub-pixels 2 may include at least two types of sub-pixels 2 having different light-emitting colors. FIG. 1 schematically shows sub-pixels 2_1 and sub-pixels 2_2 having different light-emitting colors.

As shown in FIG. 2, the sub-pixels 2 includes a light-emitting element 20. In some embodiments of the present disclosure, the light-emitting element 20 includes any one of an Organic Light Emitting Diode (OLED), a Micro Light Emitting Diode (Micro-LED), or a Quantum Light Emitting Diode (QLED).

As shown in FIG. 2, the light-emitting element 20 includes a first electrode 201, a light-emitting layer 203, a second electrode 202, and a common layer 204. The common layer 204 can enhance the migration and recombination efficiency of carriers.

In some embodiments of the present disclosure, as shown in FIG. 2, the common layer 204 includes a first sub-common layer 2041 located between the first electrode 201 and the light-emitting layer 203, and a second sub-common layer 2042 located between the second electrode 202 and the light-emitting layer 203.

In some embodiments of the present disclosure, the first electrodes 201 of different sub-pixels 2 are independent of each other, and the second electrodes 202 of the sub-pixels 2 are electrically connected to each other.

In some embodiments of the present disclosure, the first electrode 201 includes an anode, and the second electrode 202 includes a cathode. The first sub-common layer 2041 includes one or more of a Hole Injection Layer (HIL), a Hole Transport Layer (HTL), and a Hole Block Layer (HBL). The second sub-common layer 2042 includes one or more of an Electron Injection Layer (EIL), an Electron Transport Layer (ETL), and an Electron Block Layer (EBL).

As shown in FIG. 1 and FIG. 2, the display panel further includes a first pixel definition layer 31 located on a side of the first electrode 201 away from the substrate 1, and a second pixel definition layer 32 located on a side of the first pixel definition layer 31 away from the substrate 1.

FIG. 3 is a top view of a first pixel definition layer shown in FIG. 1 according to some embodiments of the present disclosure. Referring to FIG. 2 and FIG. 3, the first pixel definition layer 31 includes a first pixel opening K11 and a first opening K12. The first opening K12 at least partially surrounds the first pixel opening K11. In some embodiments of the present disclosure, both the first pixel opening K11 and the first opening K12 penetrate the first pixel definition layer 31, and the first pixel opening K11 can expose at least part of the first electrode 201 (not shown in FIG. 3).

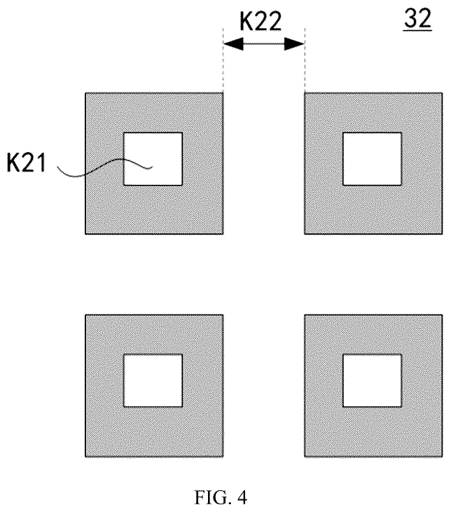

FIG. 4 is a top view of a second pixel definition layer shown in FIG. 1 according to some embodiments of the present disclosure. Referring to FIG. 2 and FIG. 4, the second pixel definition layer 32 includes a second pixel opening K21 and a second opening K22, and the second opening K22 at least partially surrounds the second pixel opening K21. In some embodiments of the present disclosure, both the second pixel opening K21 and the second opening K22 penetrate the second pixel definition layer 32, and the second pixel opening K21 can expose at least part of the first electrode 201. As shown in FIG. 2, along a direction perpendicular to a plane of the substrate 1, the second pixel opening K21 at least partially overlaps the first pixel opening K11, and the second opening K22 at least partially overlaps the first opening K12. In some embodiments of the present disclosure, as shown in FIG. 2, the second opening K22 can expose at least part of the first opening K12.

As shown in FIG. 2, the light-emitting layer 203 is at least partially located in the first pixel opening K11 and the second pixel opening K21. The smaller one of the second pixel opening K21 and the first pixel opening K11 defines the light-emitting region of the sub-pixels 2.

As shown in FIG. 2, the display panel includes a driving function layer 4 located on a side of the substrate 1, and the driving function layer 4 includes a pixel driving circuit for driving the light-emitting element 20 to emit light. In some embodiments of the present disclosure, the driving function layer includes a semiconductor layer, a metal layer and an insulating layer that are stacked, and the metal layer includes metal structures such as electrodes and traces. The traces include scan lines and data lines electrically connected to the pixel driving circuit. Both the metal structures and the first electrode 201 of the light-emitting element reflect the ambient light incident on their surfaces, and the reflected light emitted from the display panel will affect the contrast ratio of the display panel.

In some embodiments of the present disclosure, at least one of the first pixel definition layer 31 and the second pixel definition layer 32 includes a light-shielding material. The light-shielding material may absorb external ambient light and ambient light reflected by a reflective structure inside the display panel, which is conducive to reducing the reflectivity of the display panel and improving the contrast ratio of the display panel.

In some embodiments of the present disclosure, one of the first pixel definition layer 31 and the second pixel definition layer 32 may include a Normal Pixel Definition Layer (NPDL), and the other one of the first pixel definition layer 31 and the second pixel definition layer 32 may include a Black Pixel Definition Layer (BPDL). The black pixel definition layer includes the light-shielding material having a light transmittance lower than that of the normal pixel definition layer.

When manufacturing the display panel, the light-emitting layer 203 may be manufactured using a fine metal mask, and the light-emitting layers 203 of different sub-pixels 2 are spaced apart from each other. In some embodiments of the present disclosure, the common layer 204 may be prepared using an open mask. Therefore, the common layer 204 is arranged in communication between two adjacent sub-pixels 2. That is, the common layer 204 in the display panel is generally a whole-surface structure covering all sub-pixels 2.

In the related art, when a certain sub-pixel 2 is lit up, in addition to the normal longitudinal migration process of carriers from the respective cathode and/or anode to the corresponding light-emitting layer 203, the carriers may laterally migrate between different sub-pixels 2 through the common layer 204. The lateral flow of the carriers between two adjacent sub-pixels may generate a lateral leakage current, resulting in the problem of mutual crosstalk between different sub-pixels when the display panel is displaying. For example, when the turn-on voltages between two adjacent sub-pixels 2 are adjacent to each other, the lateral leakage current may cause the steal-brightness problem in the sub-pixels 2 that do not need to be lit up.

In some embodiments of the present disclosure, as shown in FIG. 2, based on the arrangement of the first opening K12 and the second opening K22, the common layer 204 forms a first recessed structure F1 at the first opening K12, which is recessed toward a side adjacent to the substrate 1. Compared with the manner in which the first pixel definition layer 31 and the second pixel definition layer 32 are respectively formed as a flat surface at the first opening K12 and the second opening K22, the arrangement of the first opening K12 and the second opening K22 may increase the length of the common layer 204 between two adjacent sub-pixels 2. Therefore, the first opening K12 and the second opening K22 can prolong the transmission path of the leakage current between two adjacent sub-pixels 2, thereby preventing the light-emitting element from exhibiting steal-brightness and improving the display effect.

In some embodiments of the present disclosure, the first opening K12 penetrates the first pixel definition layer 31, which is beneficial to increase the angle θ12 between the sidewall S12 of the first opening K12 and the plane of the substrate 1 on a side facing away from the first opening K12, so that the recess degree of the first recessed structure F1 can be increased, thereby further prolonging the transmission path of the leakage current between two adjacent sub-pixels 2.

It can be understood that the above expression “at least partially surrounding” includes “partially surrounding” and “surrounding”. The expression “partially surrounding” refers to an open-type surrounding. For example, at least one of the first opening K12 and the second opening K22 may include a notch. FIG. 3 schematically shows that the first opening K12 includes a notch 30.

The expression “surrounding” refers to a closed-type surrounding, in other words, the first opening K12 and the second opening K22 are closed annular structures, and the surrounded sub-pixels 2 are located in the annular structure enclosed by the first opening K12 and the second opening K22.

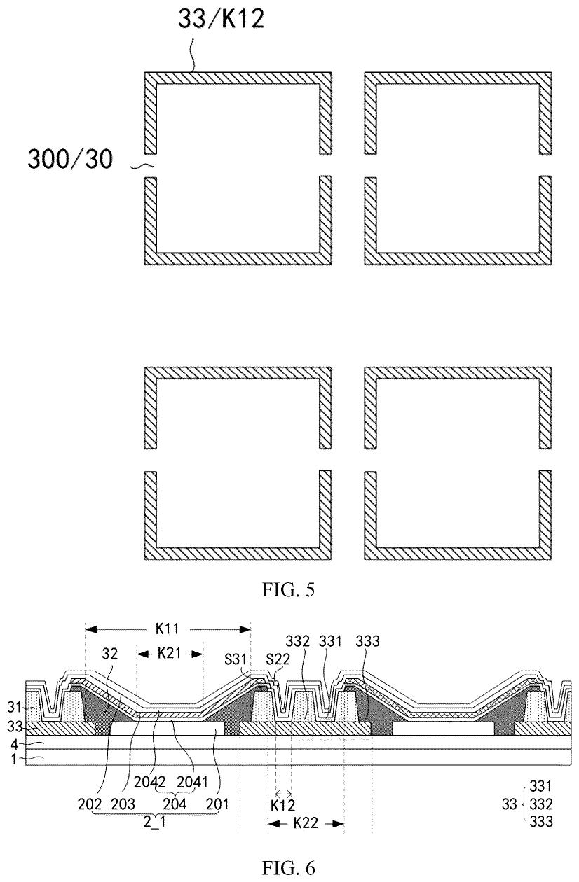

FIG. 5 is a top view of a third pixel definition layer shown in FIG. 1 according to some embodiments of the present disclosure. In some embodiments of the present disclosure, as shown in FIG. 1, FIG. 2 and FIG. 5, the display panel further includes a third pixel definition layer 33. Along the direction perpendicular to the plane of the substrate 1, the third pixel definition layer 33 at least partially overlaps the first opening K12. In some embodiments of the present disclosure, as shown in FIG. 2, the third pixel definition layer 33 includes a first sub-portion 331. Along the direction perpendicular to the plane of the substrate 1, the first sub-portion 331 at least partially overlaps the first opening K12.

As shown in FIG. 5, the shape of the orthographic projection of the third pixel definition layer 33 on the plane of the substrate 1 may be annular. As shown in FIG. 3 and FIG. 5, when the first opening K12 is formed to include a notch 30, the third pixel definition layer 33 has an annular shape with a notch 300 that corresponds to the notch 30 of the first opening K12.

As shown in FIG. 2, the common layer 204 is arranged on a side of the third pixel definition layer 33 away from the substrate 1. When the first opening K12 penetrates the first pixel definition layer 31, the angle θ12 between the sidewall S12 of the first opening K12 and the plane of the substrate 1 on a side facing away from the first opening K12 is increased, so as to ensure the leakage current suppression effect. In addition, the arrangement of the third pixel definition layer 33 can prevent the common layer 204 and the driving function layer 4 from contacting each other at the first opening K12, and can prevent the preparation process of the common layer 204 from affecting the film layers in the driving function layer 4.

According to the display panel provided by the embodiments of the present disclosure, the first pixel definition layer 31 and the second pixel definition layer 32 are arranged in the display panel, and at least one of the first pixel definition layer and the second pixel definition layer includes the light-shielding material. The light-shielding material can absorb external ambient light and absorb the ambient light reflected by metal structures inside the display panel, thereby reducing the reflectivity of the display panel.

In addition, in some embodiments of the present disclosure, the first opening K12 penetrating the first pixel definition layer 31 is arranged in the first pixel definition layer 31, and the second opening K22 penetrating the second pixel definition layer 32 is arranged in the second pixel definition layer 32, so that the first opening K12 and the second opening K22 can prolong the lateral leakage current path between two adjacent sub-pixels 2, thereby improving the steal-brightness problem of the sub-pixels, and improving the display effect of the display panel.

In addition, the arrangement of the third pixel definition layer 33 may prevent the common layer 204 and the driving function layer 4 from contacting each other at the first opening K12 and may prevent the preparation process of the common layer 204 from affecting the film layers in the driving function layer 4.

It should be noted that the arrangement of the sub-pixels 2 shown in FIG. 1 is merely illustrative. Those skilled in the art may configure the pixel arrangement of the sub-pixels 2 according to different display requirements, which is not limited in the present disclosure.

In some embodiments of the present disclosure, as shown in FIG. 2, at least part of the third pixel definition layer 33 is located within the first opening K12, and the thickness of the third pixel definition layer 33, c, is less than the depth d of the first opening K12. The thickness direction of the third pixel definition layer 33 and the depth direction of the first opening K12 are both perpendicular to the plane of the substrate 1.

Based on such arrangement, when the third pixel definition layer 33 is arranged in the first opening K12, it is possible to prevent the third pixel definition layer 33 from filling up the first opening K12. While avoiding contact between the common layer 204 and the driving function layer 4 located on both sides of the third pixel definition layer 33, an accommodation space for the common layer 204 can be retained in the first opening K12 on a side of the third pixel definition layer 33 away from the substrate 1, so that the common layer 204 can form a first recessed structure F1 recessed toward the side of the substrate 1 at this position, so as to extend the lateral leakage current path between two adjacent sub-pixels 2.

In some embodiments of the present disclosure, as shown in FIG. 2, the thickness c of the third pixel definition layer 33 and the depth d of the first opening K12 satisfy: c≤d/2.

In some embodiments of the present disclosure, as shown in FIG. 2, the angle between a sidewall S11 of the first pixel opening K11 and the plane of the substrate 1 on a side facing away from the first pixel opening K11 is θ11, and the angle between a sidewall S12 of the first opening K12 and the plane of the substrate 1 on a side facing away from the first opening K12 is θ12, where |θ11−θ12|≤5°. Based on such arrangement, the first pixel opening K11 and the first opening K12 may be formed in the same patterning process. In some embodiments of the present disclosure, the first pixel definition layer 31 includes a photosensitive material, and the patterning process includes steps of exposing, developing, and curing the initial film layer for forming the first pixel definition layer 31.

In some embodiments of the present disclosure, as shown in FIG. 2, the angle between a sidewall S21 of the second pixel opening K21 and the plane of the substrate 1 on a side facing away from the second pixel opening K21 is θ21, and the angle is formed between a sidewall S22 of the second opening K22 and the plane of the substrate 1 on a side facing away from the second opening K22 is θ22, where |θ21−θ22|≤5°. Based on such arrangement, the second pixel opening K21 and the second opening K22 may be formed in the same patterning process. In some embodiments of the present disclosure, the second pixel definition layer 32 includes a photosensitive material, and the patterning process includes steps of exposing, developing, and curing the initial film layer for forming the second pixel definition layer 32.

It should be noted that FIG. 2 is merely an example in which θ11 is greater than θ21, and the magnitude relationship between θ11 and θ21 is not limited in the present disclosure.

In some embodiments of the present disclosure, as shown in FIG. 2, the orthographic projection of the first opening K12 on the plane of the substrate 1 is at least partially located within the orthographic projection of the second opening K22 on the plane of the substrate 1. Along the direction perpendicular to the plane of the substrate 1, the angle between a sidewall S12 of the first opening K12 and the plane of the substrate 1 on a side facing away from the first opening K12 is θ12, where 60°<θ12<90°. Based on such arrangement, the sidewall S12 of the first opening K12 may be steeper, which is conducive to increasing the recess degree of the first recessed structure F1 arranged corresponding to the first opening K12, thereby further increasing the lateral leakage current path between two adjacent sub-pixels 2.

In some embodiments of the present disclosure, as shown in FIG. 2, in some embodiments of the present disclosure, at least part of the first sub-portion 331 of the third pixel definition layer 33 is located in the first opening K12. When preparing the display panel having such structure, the preparation of the third pixel definition layer 33 may be performed after the preparation of the first opening K12.

In some embodiments of the present disclosure, at least part of the third pixel definition layer 33 may be located outside the first opening K12. FIG. 6 is a cross-sectional view of a display panel according to some embodiments of the present disclosure. In some embodiments of the present disclosure, as shown in FIG. 6, the third pixel definition layer 33 is located on a side of the first pixel definition layer 31 adjacent to the substrate 1, and along the direction perpendicular to the plane of the substrate 1, the third pixel definition layer 33 at least partially overlaps the first opening K12. FIG. 6 schematically shows that the orthographic projection of the third pixel definition layer 33 on the plane of the substrate 1 covers the orthographic projection of the first opening K12 on the plane of the substrate 1.

In some embodiments of the present disclosure, along the direction perpendicular to the plane of the substrate 1, at least part of the third pixel definition layer 33 does not overlap the first opening K12, and/or at least part of the third pixel definition layer 33 does not overlap the second opening K22.

In FIG. 6, the third pixel definition layer 33 includes a first sub-portion 331, a second sub-portion 332 and a third sub-portion 333. Along the direction perpendicular to the plane of the substrate 1, the first sub-portion 331 at least partially overlaps the first opening K12, the second sub-portion 332 at least partially overlaps the first pixel definition layer 31, and the third sub-portion 333 at least partially overlaps the second pixel definition layer 32.

By adopting such arrangement, the common layer 204 and the driving function layer 4 can be isolated at the first opening K12 using the third pixel definition layer 33. In addition, since the third pixel definition layer 33 is formed prior to the first opening K12, the influence of the preparation process of the first opening K12 on the driving function layer 4 can be avoided.

In some embodiments of the present disclosure, as shown in FIG. 2 and FIG. 6, along the direction perpendicular to the plane of the substrate 1, the sidewall S22 of the second opening K22 at least partially overlaps the surface S31 of the first pixel definition layer 31 away from the substrate 1.

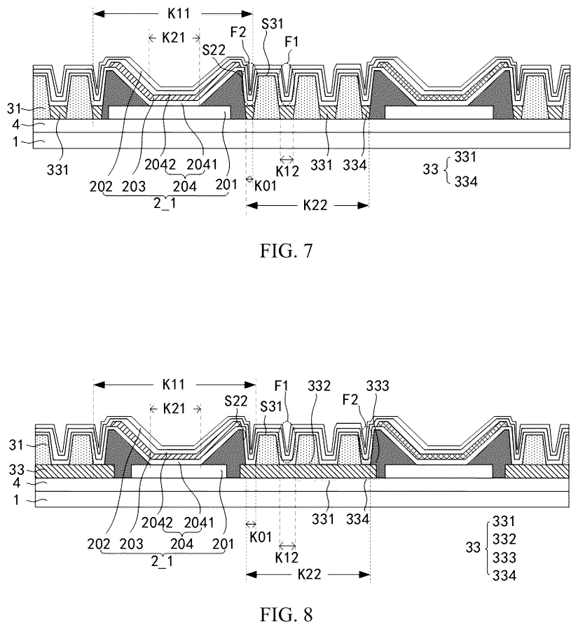

FIG. 7 is a cross-sectional view of a display panel according to some embodiments of the present disclosure, and FIG. 8 is a cross-sectional view of a display panel according to some embodiments of the present disclosure. In some embodiments of the present disclosure, as shown in FIG. 7 and FIG. 8, FIG. 7 schematically shows that at least part of the third pixel definition layer 33 is located in the first opening K12, and FIG. 8 schematically shows that at least part of the third pixel definition layer 33 is located on a side of the first pixel definition layer 31 adjacent to the substrate 1.

As shown in FIG. 7 and FIG. 8, the orthographic projection of the first opening K12 on the plane of the substrate 1 is at least partially located within the orthographic projection of the second opening K22 on the plane of the substrate 1. Along the direction perpendicular to the plane of the substrate 1, the sidewall S22 of the second opening K22 at least partially does not overlap the surface S31 of the first pixel definition layer 31 away from the substrate 1. Based on such arrangement, it is equivalent to allowing the second opening K22 at least partially overlap the first pixel opening K11 in the direction perpendicular to the plane of the substrate 1, and the overlapping portion of the two is defined as a first overlapping portion K01.

As shown in FIG. 7 and FIG. 8, the third pixel definition layer 33 further includes a fourth sub-portion 334. Along the direction perpendicular to the plane of the substrate 1, the fourth sub-portion 334 at least partially overlaps the first overlapping portion K01. In other words, the orthographic projection of the fourth sub-portion 334 on the plane of the substrate 1 may be located within the orthographic projection of the first pixel opening K11 on the plane of the substrate 1.

Based on such arrangement, as shown in FIG. 7 and FIG. 8, the common layer 204 may form a second undulating structure F2 on a side of the fourth sub-portion 334 away from the substrate 1, thereby increasing the number of undulating structures in the common layer 204 that are located between two adjacent sub-pixels 2, further prolonging the lateral leakage current path of carriers between two adjacent sub-pixels 2, and suppressing the lateral leakage current problem.

FIG. 7 and FIG. 8 schematically shows that two first undulating structures F1 and two second undulating structures F2 are included between two adjacent sub-pixels 2.

In some embodiments of the present disclosure, the third pixel definition layer 33 and the first pixel definition layer 31 are made of the same material, so as to improve the surface adhesion between the third pixel definition layer 33 and the first pixel definition layer 31, and to reduce the possibility of the third pixel definition layer 33 peeling off from the surface of the first pixel definition layer 31.

In some embodiments of the present disclosure, at least one of the first pixel definition layer 31, the second pixel definition layer 32 and the third pixel definition layer 33 is formed of the photosensitive material. Based on such arrangement, during the preparation of the corresponding film layer, the desired opening can be formed in the corresponding layer by coating the initial film layer and exposing the initial film layer through a mask plate, an additional mask layer is not required to be formed on the surface of the initial film layer, and thus a process for removing the mask layer is not required to be introduced.

Since the process of removing the mask layer typically requires the use of a stripping solution, the film layer in the display panel, such as the film layer formed of a light-shielding material, may experience discoloration when exposed to the stripping solution, thereby affecting the reflectivity of the display panel. Therefore, by adopting the arrangement provided by the embodiments of the present disclosure, the process of removing the mask layer can be avoided, thereby ensuring that the performance of the film layer in the display panel, such as the film layer including the light-shielding material, is not affected. Such arrangement not only simplifies the preparation process of the display panel, but also ensures that the display panel has low reflectivity.

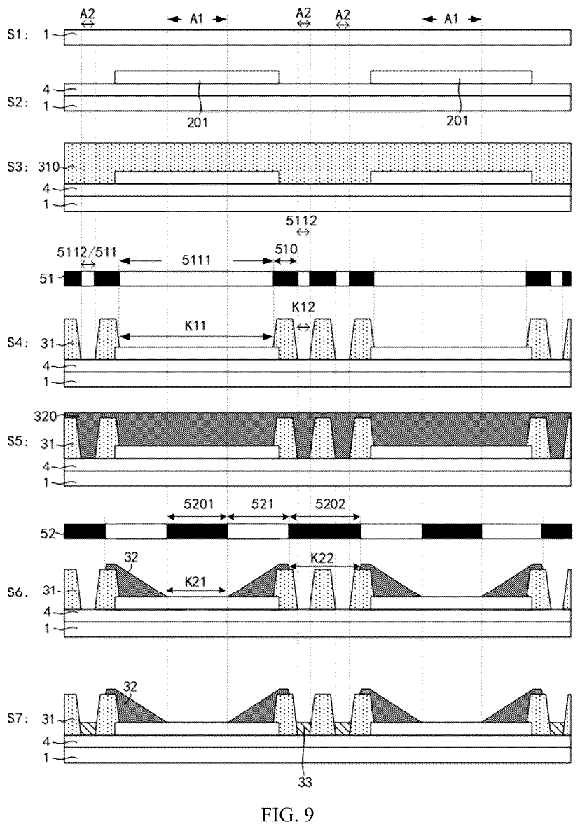

The present disclosure further provides a method for preparing a display panel. FIG. 9 is a schematic flowchart of a method for preparing a display panel according to some embodiments of the present disclosure. As shown in FIG. 9, the method includes as follows.

Step S1: a substrate 1 is provided. In some embodiments of the present disclosure, the substrate 1 includes a first region A1 and a second region A2. The first region A1 may be a light-emitting region of the sub-pixels, that is, the region where the second pixel opening K21 of the display panel shown in FIG. 2 is located. The second region A2 may be the region where the first opening K12 of the display panel shown in FIG. 2 is located. The second region A2 at least partially surrounds the first region A1.

Step S2: a first electrode 201 is formed on a side of the substrate 1. The orthographic projection of the first electrode 201 on the plane of the substrate 1 is at least partially located in the first region A1, that is, the first electrode 201 at least partially overlap the first region A1 in the direction perpendicular to the plane of the substrate 1. The orthographic projection of the first electrode 201 on the plane of the substrate 1 is at least partially offset from the second region A2. For example, the first electrode 201 is arranged to avoid the second region A2.

In some embodiments of the present disclosure, as shown in FIG. 9, the method for preparing the display panel according to the embodiments of the present disclosure further includes a step of forming a driving function layer 4 on a side of the substrate 1. The driving function layer 4 includes a pixel driving circuit for driving the light-emitting element to light up. It should be noted that, the driving function layer 4 is schematically simplified in the embodiments of the present disclosure. In fact, the driving function layer 4 may include a plurality of film layers, and the plurality of film layers include a metal layer, an insulating layer, a semiconductor layer, etc. The specific structure of the driving function layer 4 is not limited in the present disclosure.

Step S3: a first initial pixel definition layer 310 is formed on a side of the first electrode 201 away from the substrate 1. The orthographic projection of the first initial pixel definition layer 310 on the plane of the substrate 1 may cover the first region A1 and the second region A2, that is, the orthographic projection of the first initial pixel definition layer 310 on the plane of the substrate 1 may cover the first electrode 201.

Step S4: a first pixel opening K11 and a first opening K12 are formed in the first initial pixel definition layer 310 through a first full-grayscale mask plate 51, to obtain a first pixel definition layer 31 including the first pixel opening K11 and the first opening K12. As shown in FIG. 9, the orthographic projection of the first pixel opening K11 on the plane of the substrate 1 is at least partially located in the first region A1, and the orthographic projection of the first opening K12 on the plane of the substrate 1 is at least partially located in the second region A2. Both the first pixel opening K11 and the first opening K12 penetrate the first pixel definition layer 31. The first pixel opening K11 exposes at least part of the first electrode 201. As shown in FIG. 1 and FIG. 3, the first opening K12 at least partially surrounds the first pixel opening K11.

In some embodiments of the present disclosure, the first initial pixel definition layer 310 may include a positive photosensitive material or a negative photosensitive material. Taking the first initial pixel definition layer 310 including the positive photosensitive material as an example, as shown in FIG. 9, the first full-grayscale mask plate 51 includes a first light-transmitting region and a first non-light-transmitting region 510. In some embodiments of the present disclosure, the first full-grayscale mask plate 51 may include a plurality of first light-transmitting regions, and the plurality of first light-transmitting regions include a first light-transmitting sub-region 5111 and a second light-transmitting sub-region 5112. When exposing the first initial pixel definition layer 310, the first light-transmitting sub-region 5111 may correspond to the first region A1, and the second light-transmitting sub-region 5112 may correspond to the second region A2.

After the exposure and development processes, a part of the first initial pixel definition layer 310 corresponding to the first light-transmitting sub-region 5111 may be completely removed to form the first pixel opening K11, a part of the first initial pixel definition layer 310 corresponding to the second light-transmitting sub-region 5112 may be completely removed to form the first opening K12, and a part of the first initial pixel definition layer 310 corresponding to the first non-light-transmitting region 510 may be retained to form the non-opening portion of the first pixel definition layer 31.

Step S5: a second initial pixel definition layer 320 is formed on a side of the first pixel definition layer 31 away from the substrate 1. As shown in FIG. 9, the second initial pixel definition layer 320 covers the first pixel opening K11 and the first opening K12.

Step S6: a second pixel opening K21 and a second opening K22 are formed in the second initial pixel definition layer 320 through the second full-grayscale mask plate 52, to obtain a second pixel definition layer 32 including the second pixel opening K21 and the second opening K22. The second pixel opening K21 and the second opening K22 both penetrate the second pixel definition layer 32. The second pixel opening K21 exposes at least part of the first electrode 201. As shown in FIG. 1, the second opening K22 at least partially surrounds the second pixel opening K21. Along the direction perpendicular to the plane of the substrate 1, the second opening K22 at least partially overlaps the first opening K12. As shown in FIG. 9, along the direction perpendicular to the plane of the substrate 1, one second opening K22 overlaps two first openings K12.

In some embodiments of the present disclosure, the second initial pixel definition layer 320 may include a positive photosensitive material or a negative photosensitive material. Taking the second initial pixel definition layer 320 including the negative photosensitive material as an example, as shown in FIG. 9, the second full-grayscale mask plate 52 includes a second non-light-transmitting region and a second light-transmitting region 521. In some embodiments of the present disclosure, the second full-grayscale mask plate 52 may include a plurality of second non-light-transmitting regions, and the plurality of second non-light-transmitting regions include a first non-light-transmitting sub-region 5201 and a second non-light-transmitting sub-region 5202. When exposing the second initial pixel definition layer 320, the first non-light-transmitting sub-region 5201 may correspond to the first region A1, and the second non-light-transmitting sub-region 5202 may correspond to the second region A2.

After the exposure and development processes, a part of the second initial pixel definition layer 320 corresponding to the first non-light-transmitting region 5201 may be completely removed to form the second pixel opening K21, a part of the second initial pixel definition layer 320 corresponding to the second non-light-transmitting region 5202 may be completely removed to form the second opening K22, and a part of the second initial pixel definition layer 320 corresponding to the second light-transmitting region 521 may be retained to form the non-opening portion of the second pixel definition layer 32.

Step S7: a third pixel definition layer 33 is formed. The third pixel definition layer 33 at least partially overlaps the first opening K12 along the direction perpendicular to the plane of the substrate 1.

In some embodiments of the present disclosure, as shown in FIG. 2 and FIG. 9, after the preparation of the first pixel definition layer 31, the second pixel definition layer 32 and the third pixel definition layer 33 as shown in FIG. 2, the method for preparing the display panel according to the embodiments of the present disclosure further includes the following steps:

A light-emitting layer 203, a common layer 204, and a second electrode 202 are formed on a side of the second pixel definition layer 32 away from the substrate 1, to obtain a display panel having the structure shown in FIG. 2.

In some embodiments of the present disclosure, at least one of the first initial pixel definition layer 310 and the second initial pixel definition layer 320 includes a light-shielding material, so that at least one of the first pixel definition layer 31 and second pixel definition layer 32 that are subsequently formed includes a light-shielding material. The light-shielding material can absorb external ambient light and absorb the ambient light reflected by metal structures inside the display panel, thereby reducing the reflectivity of the display panel.

In addition, in some embodiments of the present disclosure, the first opening K12 penetrating the first pixel definition layer 31 is arranged in the first pixel definition layer 31, and the second opening K22 penetrating the second pixel definition layer 32 is arranged in the second pixel definition layer 32, so that the first opening K12 and the second opening K22 can prolong the lateral leakage current path between two adjacent sub-pixels 2, thereby improving the steal-brightness problem of the sub-pixels, and improving the display effect of the display panel.

In addition, the arrangement of the third pixel definition layer 33 may prevent the common layer 204 and the driving function layer 4 from contacting each other at the first opening K12 and may prevent the preparation process of the common layer 204 from affecting the film layers in the driving function layer 4, thereby improving the reliability of each film layer in the driving function layer 4.

In the related art, one way of preparing the opening in the pixel definition layer includes: forming a mask layer on the surface of the pixel definition layer, for example, the mask layer may be a photoresist or an Indium Zinc Oxide (IZO) layer. The transmittance of the region of the mask layer corresponding to the opening is different from the transmittance of other positions. Under the blocking effect of the mask layer, the pixel definition layer is etched. This method requires the introduction of steps for the preparation and removal of the mask layer during the process, making the process relatively complex. In addition, when the opening is formed in the pixel definition layer using the etching process and the mask layer is removed, the etching process can easily have an adverse effect on the film layers in the display panel. For example, when the second pixel definition layer formed of the light-shielding material encounters the stripping solution used in the etching process, a fading problem may occur, which affects the reflectivity of the display panel.

In some embodiments of the present disclosure, at least one of the first pixel definition layer 31, the second pixel definition layer 32 and the third pixel definition layer 33 is formed of the photosensitive material. During the preparation of the corresponding film layer, the desired opening can be formed in the corresponding layer by coating the initial film layer and exposing the initial film layer through a mask plate, an additional mask layer is not required to be formed on the surface of the initial film layer, and thus an etching process for removing the mask layer is not required to be introduced. Therefore, by adopting the arrangement provided by the embodiments of the present disclosure, on the one hand, the preparation process of the display panel can be simplified, and on the other hand, it can be ensured that the performance of the film layer in the display panel, such as the film layer including the light-shielding material, is not affected, thereby ensuring that the display panel maintains a low reflectivity.

In some embodiments of the present disclosure, as shown in FIG. 9, the method for forming the first pixel definition layer 31 in step S4 includes as follows.

The first initial pixel definition layer 310 is exposed, developed and cured to at least completely remove a part of the first initial pixel definition layer 310 located in the first region A1 and a part of the first initial pixel definition layer 310 located in the second region A2, to obtain the first pixel definition layer 31. The first pixel definition layer 31 includes a first pixel opening K11 at least partially located in the first region A1 and a first opening K12 at least partially located in the second region A2.

In some embodiments of the present disclosure, as shown in FIG. 9, the method for forming the second pixel definition layer 32 in step S6 includes as follows.

The second initial pixel definition layer 320 is exposed, developed and cured to at least completely remove a part of the second initial pixel definition layer 320 located in the first region A1 and a part of the second initial pixel definition layer 320 located in the second region A2, to obtain a second pixel definition layer 32. The second pixel definition layer 32 includes a second pixel opening K21 at least partially located in the first region A1 and a second opening K22 at least partially located in the second region A2.

In some embodiments of the present disclosure, as shown in FIG. 9, the area of the first light-transmitting sub-region 5111 may be greater than the area of the first non-light-transmitting sub-region 5201. Based on such arrangement, the area of the prepared first pixel opening K11 may be greater than the area of the second pixel opening K21. FIG. 9 schematically shows that the orthographic projection of the first pixel opening K11 on the plane of the substrate 1 covers the orthographic projection of the second pixel opening K21 on the plane of the substrate 1. In this case, the second pixel opening K21 having a relatively small area determines the light-emitting region of the sub-pixels.

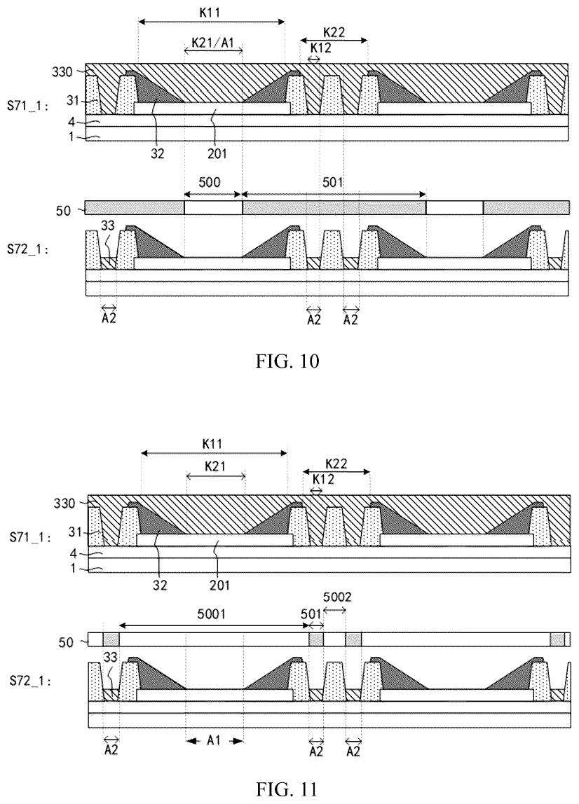

In the preparation of the third pixel definition layer 33, in some embodiments of the present disclosure, the preparation of the third pixel definition layer 33 may be performed after the preparation of the second pixel definition layer 32. FIG. 10 is a schematic diagram of a method for preparing a third pixel definition layer according to some embodiments of the present disclosure. As shown in FIG. 10, the method for forming the third pixel definition layer 33 in step S7 shown in FIG. 9 includes as follows.

Step S71_1: the third initial pixel definition layer 330 is formed on a side of the second pixel definition layer 32 away from the substrate 1. The orthographic projection of the third initial pixel definition layer 330 on the plane of the substrate 1 covers the orthographic projection of the second pixel opening K21 on the plane of the substrate 1 and the orthographic projection of the second opening K22 on the plane of the substrate 1.

Step S72_1: the third initial pixel definition layer 330 is exposed, developed and cured, a part of the third initial pixel definition layer 330 located in the first region A1 is at least completely removed, a part of the third initial pixel definition layer 330 located in the second region A2 is at least partially removed, and a part of the third initial pixel definition layer 330 located in the second region A2 is retained, to obtain a third pixel definition layer 33 at least partially located in the second region A2.

In some embodiments of the present disclosure, as shown in FIG. 10, the exposure of the third initial pixel definition layer 330 may be performed using a half-grayscale mask plate 50.

In some embodiments of the present disclosure, the third initial pixel definition layer 330 may include a positive photosensitive material or a negative photosensitive material. Taking the third initial pixel definition layer 330 including a positive photosensitive material as an example, as shown in FIG. 10, the half-grayscale mask plate 50 includes a full-light-transmitting region 500 and a half-light-transmitting region 501. When exposing the third initial pixel definition layer 330, at least part of the full-light-transmitting region 500 may correspond to the first region A1, and at least part of the half-light-transmitting region 501 may correspond to the second region A2. After the exposure and development processes, a part of the third initial pixel definition layer 330 corresponding to the full-light-transmitting region 500 may be completely removed, and a part of the third initial pixel definition layer 330 corresponding to the half-light-transmitting region 501 may be partially retained, thereby forming the third pixel definition layer 33.

When aligning the half-grayscale mask plate 50 with the display panel to be exposed, in some embodiments of the present disclosure, as shown in FIG. 10, the half-light-transmitting region 501 not only corresponds to the first opening K12, but also corresponds to a partial region around the first opening K12. As shown in FIG. 10, a part of the third initial pixel definition layer 330 located above the second pixel definition layer 32 and a part of the third initial pixel definition layer 330 located between two adjacent first openings K12 both have smaller thicknesses, so that this part can be completely removed through exposure of the half-light-transmitting region 501.

FIG. 11 is a schematic flowchart of another method for preparing a third pixel definition layer according to some embodiments of the present disclosure. In some embodiments of the present disclosure, as shown in FIG. 11, the half-light-transmitting region 501 of the half-grayscale mask plate 50 may only correspond to the first opening K12.

In some embodiments of the present disclosure, as shown in FIG. 11, the full-light-transmitting region includes a first full-light-transmitting sub-region 5001 and a second full-light-transmitting sub-region 5002. When exposing the third initial pixel definition layer 330, the half-light-transmitting region 501 may only correspond to the first opening K12. The first full-light-transmitting sub-region 5001 corresponds to the first region A1 and regions located on both sides of the first region A1, so as to completely remove a part of the third initial pixel definition layer 330 located in the first region A1 and a part of the third initial pixel definition layer 330 located above the second pixel definition layer 32. In addition, the second full-light-transmitting sub-region 5002 corresponds to a part of the third initial pixel definition layer 330 located between two adjacent first openings K12, so as to completely remove a part of the third initial pixel definition layer 330 located between two adjacent first openings K12.

In some embodiments of the present disclosure, at least part of the third pixel definition layer 33 may be located in the first opening K12, and FIG. 9, FIG. 10, and FIG. 11 all schematically show that the third pixel definition layer 33 is completely located in the first opening K12.

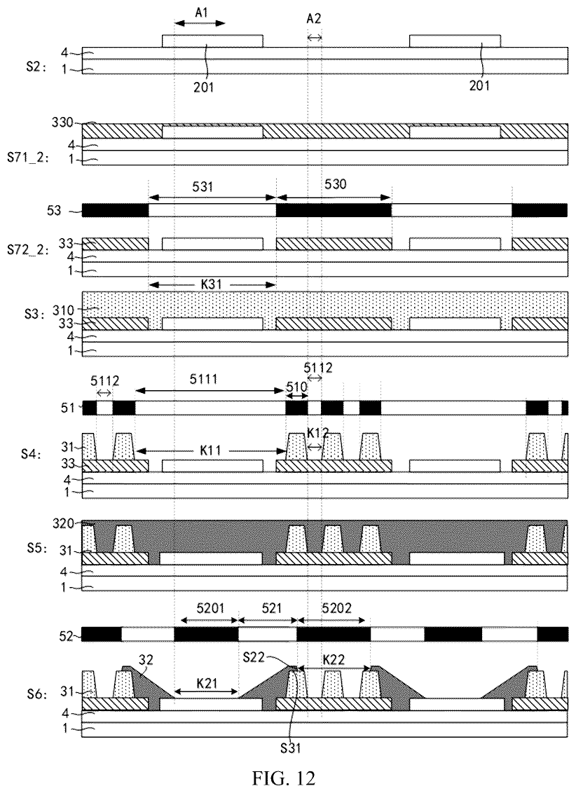

In some embodiments of the present disclosure, the present disclosure may also configure the preparation of the third pixel definition layer 33 before the preparation of the first pixel definition layer 31. FIG. 12 is a schematic flowchart of a method for preparing a display panel according to some embodiments of the present disclosure. As shown in FIG. 12, the step of preparing the third pixel definition layer 33 may occur after the step of preparing the first electrode 201 shown in step S2 of FIG. 9 and before the step of preparing the first initial pixel definition layer 310 shown in step S3.

As shown in FIG. 12, the method for forming the third pixel definition layer 33 in step S7 shown in FIG. 9 includes as follows.

Step S71_2: a third initial pixel definition layer 330 is formed on a side of the first electrode 201 away from the substrate 1. The orthographic projection of the third initial pixel definition layer 330 on the plane of the substrate 1 at least partially covers the first region A1 and the second region A2. As shown in FIG. 12, the orthographic projection of the third initial pixel definition layer 330 on the plane of the substrate 1 at least partially covers the orthographic projection of the first electrode 201 on the plane of the substrate 1.

Step S72_2: the third initial pixel definition layer 330 is exposed, developed and cured using the third full-grayscale mask plate 53, and a part of the third initial pixel definition layer 330 located in the first region A1 is at least removed, to obtain a third pixel definition layer 33 at least partially located in the second region A2. In some embodiments of the present disclosure, as shown in FIG. 12, the third pixel definition layer 33 may include a third pixel opening K31, and the third pixel opening K31 exposes at least part of the first electrode 201.

In some embodiments of the present disclosure, the third initial pixel definition layer 330 may include a positive photosensitive material or a negative photosensitive material. Taking the third initial pixel definition layer 330 including the positive photosensitive material as an example, as shown in FIG. 12, the third full-grayscale mask plate 53 includes a third light-transmitting region 531 and a third non-light-transmitting region 530.

After the exposure and development processes, a part of the third initial pixel definition layer 330 corresponding to the third light-transmitting region 531 may be completely removed to obtain the third pixel opening K31, and a part of the third initial pixel definition layer 330 corresponding to the third non-light-transmitting region 530 may not be removed, so as to retain the non-opening portion of the third pixel definition layer 33.

After obtaining the third pixel definition layer 33, the above step S3 may be performed, that is, the first initial pixel definition layer 310 is formed on a side of the third pixel definition layer 33 away from the substrate 1. As shown in FIG. 12, the orthographic projection of the first initial pixel definition layer 310 on the plane of the substrate 1 covers the third pixel opening K31 and the non-opening portion of the third pixel definition layer 33.

Then, the above step S4 is performed, that is, the first pixel definition layer 31 is formed through the first full-grayscale mask plate 51.

It should be noted that, as shown in FIG. 12, the area of the first light-transmitting sub-region 5111 is larger than the area of the third pixel opening K31, so that the area of the obtained first pixel opening K11 is larger than the area of the third pixel opening K31, which is merely an illustration. In some embodiments of the present disclosure, the area of the first light-transmitting sub-region 5111 is smaller than or equal to the area of the third pixel opening K31, which is not limited in the present disclosure.

After obtaining the first pixel definition layer 31, the above steps S5 and S6 are continued to form the second pixel definition layer 32, thereby obtaining the display panel having the structure shown in FIG. 6.

When preparing the second pixel definition layer 32, for example, as shown in FIG. 9 and FIG. 12, in some embodiments of the present disclosure, the second non-light-transmitting sub-region 5202 of the second full-grayscale mask plate 52 may avoid the first pixel opening K11. Based on such arrangement, after exposure, development and curing processes, along the direction perpendicular to the plane of the substrate 1, the sidewall S22 of the second opening K22 may at least partially overlap the surface S31 of the first pixel definition layer 31 away from the substrate 1, to obtain the display panel having the structure shown in FIG. 2 or FIG. 6.

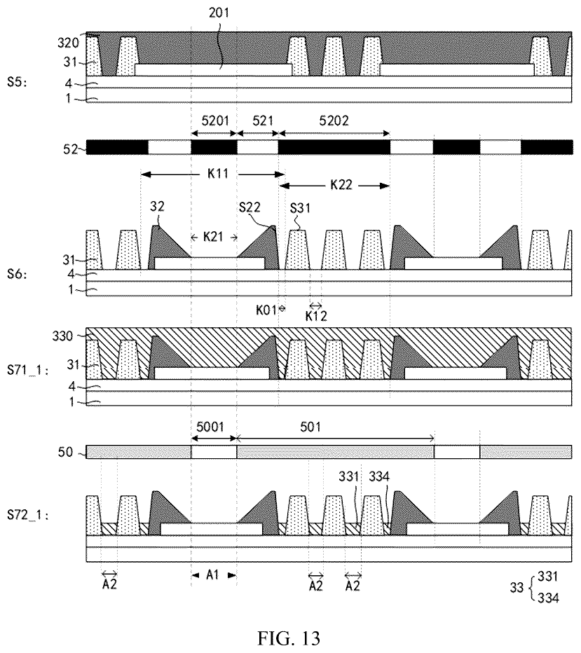

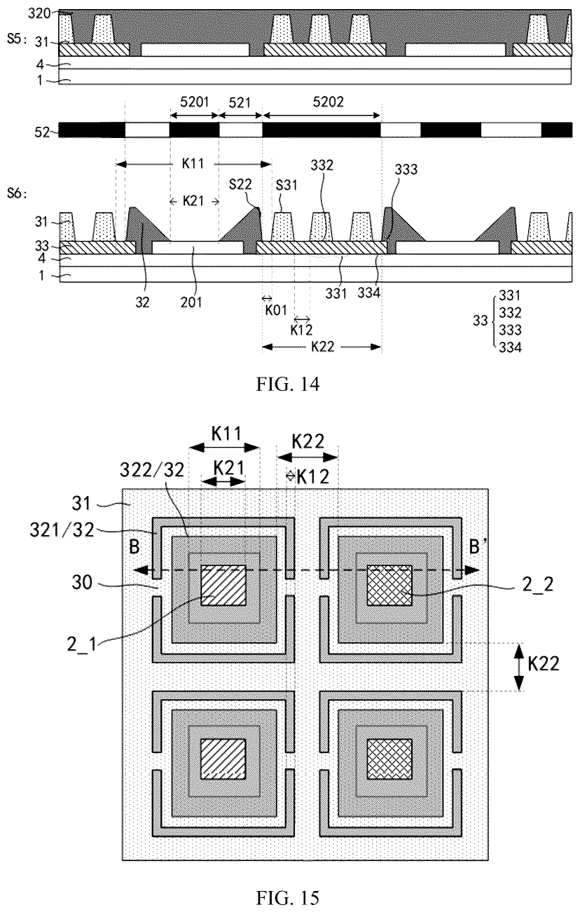

FIG. 13 is a schematic flowchart of a method for preparing a display panel according to some embodiments of the present disclosure; and FIG. 14 is a schematic flowchart of a method for preparing a display panel according to some embodiments of the present disclosure In some embodiments of the present disclosure. As shown in FIG. 13 and FIG. 14, when the second full-grayscale mask plate 52 is aligned with the display panel to be exposed to prepare the second pixel definition layer 32, the second non-light-transmitting sub-region 5202 of the second full-grayscale mask plate 52 may also correspond to the first pixel opening K11.

Based on such arrangement, after step S6, the second opening K22 may at least partially overlap the first pixel opening K11 to form the first overlapping portion K01 shown in FIG. 7 and FIG. 8. That is, along the direction perpendicular to the plane of the substrate 1, the sidewall S22 of the second opening K22 may at least partially not overlap the surface S31 of the first pixel definition layer 31 away from the substrate 1.

As shown in FIG. 13, after obtaining the second pixel definition layer 32 through step S6, the step S71_1 and the step S72_1 continue to be performed. In the step S72_1, when the half-grayscale mask plate 50 is aligned with the display panel to be exposed, the half-light-transmitting region 501 of the half-grayscale mask plate 50 may further correspond to the first overlapping portion K01, so that a part of the third initial pixel definition layer 330 corresponding to the first overlapping portion K01 may be partially removed to form a fourth sub-portion 334 of the third pixel definition layer 33 at the position of the first overlapping portion K01. As shown in FIG. 7, the subsequent common layer 204 may form a second recessed structure F2 on a side of the fourth sub-portion 334 away from the substrate 1.

As shown in FIG. 14, after obtaining the second pixel definition layer 32 through step S6, the position of the previously formed third pixel definition layer 33 overlapping the first overlapping portion K01 corresponds to the fourth sub-portion 334. As shown in FIG. 8, the subsequent common layer 204 may form a second recessed structure F2 on a side of the fourth sub-portion 334 away from the substrate 1.

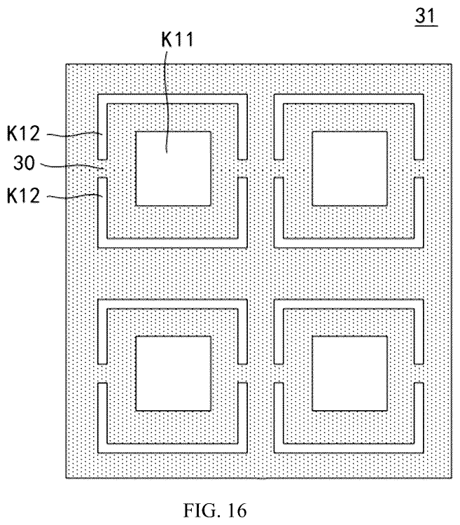

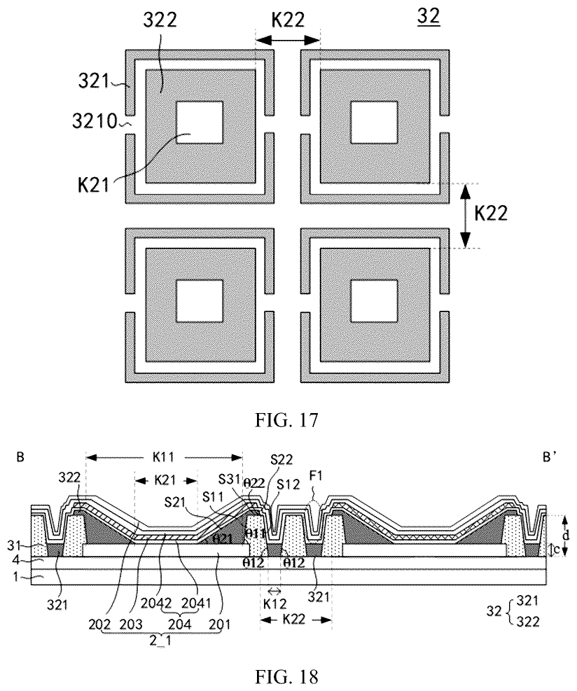

The present disclosure further provides a display panel. FIG. 15 is an enlarged schematic diagram of a region where four sub-pixels are located in a display panel according to some embodiments of the present disclosure; FIG. 16 is a top view of a first pixel definition layer shown in FIG. 15 according to some embodiments of the present disclosure; FIG. 17 is a top view of a second pixel definition layer shown in FIG. 15 according to some embodiments of the present disclosure; and FIG. 18 is a cross-sectional view along line BB′ shown in FIG. 15 according to some embodiments of the present disclosure. As shown in FIG. 15, FIG. 16, FIG. 17 and FIG. 18, the display panel includes a substrate 1, a first pixel definition layer 31, a second pixel definition layer 32 and sub-pixels 2. The sub-pixels 2 include a first electrode 201, a second electrode 202, a light-emitting layer 203, and a common layer 204. In some embodiments of the present disclosure, the common layer 204 includes a first sub-common layer 2041 and a second sub-common layer 2042. The first electrode 201 is located on a side of the substrate 1.

The first pixel definition layer 31 is located on a side of the first electrode 201 away from the substrate 1, and the first pixel definition layer 31 includes a first pixel opening K11. The first pixel opening K11 exposes at least part of the first electrode 201. The second pixel definition layer 32 is located on a side of the first pixel definition layer 31 away from the substrate K1, and the second pixel definition layer 32 includes a second pixel opening K22. The second pixel opening K22 penetrates the second pixel definition layer 32, and the second pixel opening K21 exposes at least part of the first electrode 201.

As shown in FIG. 16 and FIG. 18, the first pixel definition layer 31 further includes a first opening K12, and the first opening K12 at least partially surrounds the first pixel opening K11. FIG. 16 schematically shows that the first opening K12 includes a notch 30, and the first opening K12 partially surrounds the first pixel opening K11. The first opening K12 penetrates the first pixel definition layer 31.

As shown in FIG. 17 and FIG. 18, the second pixel definition layer 32 further includes a first groove K22 at least partially surrounding the second pixel opening K21.

As shown in FIG. 18, along the direction perpendicular to the plane of the substrate 1, the first groove K22 partially penetrates the second pixel definition layer 32 at least partial positions, and the first groove K22 at least partially overlaps the first opening K12.

As shown in FIG. 17 and FIG. 18, the second pixel definition layer 32 includes a first portion 321 located in the first opening K12, and a second portion 322 located between the first groove K22 and the second pixel opening K21. In the direction perpendicular to the plane of the substrate 1, the first portion 321 is located on a side of at least part of the first groove K22 adjacent to the substrate 1. As shown in FIG. 18, at least part of the surface of the first groove K22 adjacent to the substrate 1 is located in the first opening K12. Taking the orientation shown in FIG. 18 as an example, at least part of the bottom surface of the first groove K22 is located in the first opening K12.

As shown in FIG. 17, the first portion 321 partially surrounds the second pixel opening K21, and the first portion 321 includes a notch 3210. The notch 3210 may correspond to the notch 30 of the first opening K12 shown in FIG. 16.

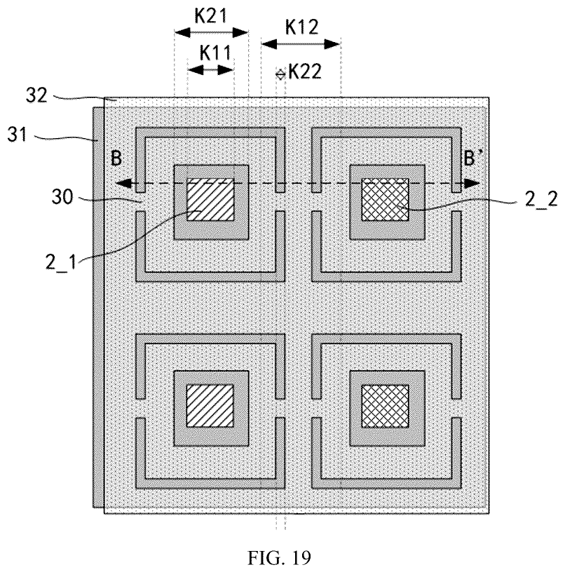

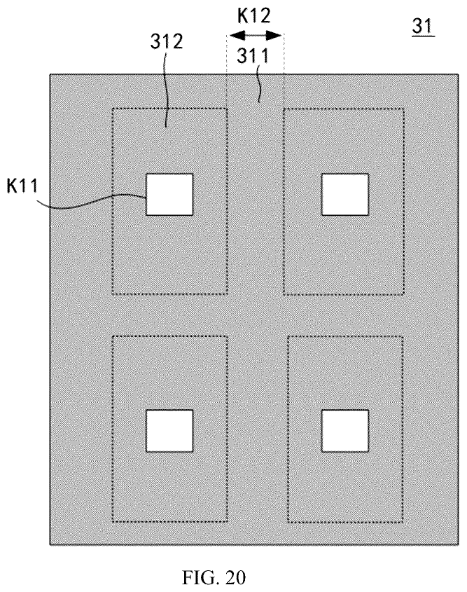

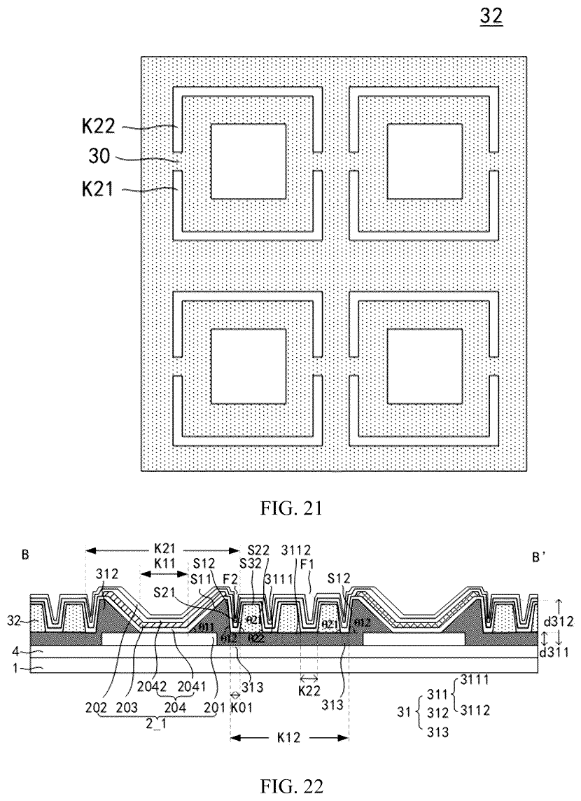

FIG. 19 is an enlarged schematic diagram of a region where four sub-pixels are located in a display panel according to some embodiments of the present disclosure; FIG. 20 is a top view of a first pixel definition layer shown in FIG. 19 according to some embodiments of the present disclosure; FIG. 21 is a top view of a second pixel definition layer shown in FIG. 19 according to some embodiments of the present disclosure; and FIG. 22 is a cross-sectional view along line BB′ shown in FIG. 19 according to some embodiments of the present disclosure. As shown in FIG. 19, FIG. 20, FIG. 21 and FIG. 22, in some embodiments of the present disclosure, the first pixel definition layer 31 includes a first pixel opening K11 and a second groove K12. The first pixel opening K11 penetrates the first pixel definition layer 31, and the second groove K12 partially penetrates the first pixel definition layer 31.

As shown in FIG. 21, the second pixel definition layer 32 includes a second pixel opening K21 and a second opening K22. In some embodiments of the present disclosure, as shown in FIG. 21, the second opening K22 at least partially surrounds the second pixel opening K21. FIG. 21 schematically shows that the second opening K22 includes a notch 30, and the second opening K22 partially surrounds the second pixel opening K22.

As shown in FIG. 22, along the direction perpendicular to the plane of the substrate 1, the second pixel opening K21 and the second opening K22 both penetrate the second pixel definition layer 32, and the second opening K22 at least partially overlaps the second groove K12. At least part of the first pixel definition layer 31 is located on a side of the second opening K22 adjacent to the substrate 1.

In some embodiments of the present disclosure, as shown in FIG. 20 and FIG. 22, the first pixel definition layer 31 includes a first sub-pixel definition layer 311 and a second sub-pixel definition layer 312. In the direction perpendicular to the plane of the substrate 1, the first sub-pixel definition layer 311 at least partially overlaps the second groove K22. The first sub-pixel definition layer 311 is located at a side of at least part of the second groove K12 adjacent to the substrate 1. The second sub-pixel definition layer 312 is located between the first pixel opening K11 and the second groove K12. The first sub-pixel definition layer 311 at least partially surrounds the second sub-pixel definition layer 312.

In some embodiments of the present disclosure, as shown in FIG. 22, the distance d311 from a surface of the first sub-pixel definition layer 311 away from the substrate 1 to the substrate 1 is less than a distance d312 from a surface of the second sub-pixel definition layer 312 away from the substrate 1 to the substrate 1.

In some embodiments of the present disclosure, as shown in FIG. 22, the first sub-pixel definition layer 311 includes a first sub-portion 3111 and a second sub-portion 3112. Along the direction perpendicular to the plane of the substrate 1, the first sub-portion 3111 at least partially overlaps the second opening K22, and the second sub-portion 3112 at least partially does not overlap the second opening K22. In the direction perpendicular to the plane of the substrate 1, the first sub-portion 3111 is located on a side of the second opening K22 adjacent to the substrate 1.

In some embodiments of the present disclosure, at least one of the first pixel definition layer 31 and the second pixel definition layer 32 includes a light-shielding material. In some embodiments of the present disclosure, the first pixel definition layer 31 shown in FIG. 18 may include a light-transmitting material, and the second pixel definition layer 32 may include a light-shielding material. For example, the first pixel definition layer 31 may include a Normal Pixel Definition Layer (NPDL), and the second pixel definition layer 32 may include a Black Pixel Definition Layer (BPDL).

In some embodiments of the present disclosure, the first pixel definition layer 31 shown in FIG. 22 includes a light-shielding material, and the second pixel definition layer 32 shown in FIG. 22 includes a light-transmitting material. For example, the first pixel definition layer 31 may include the black pixel definition layer, and the second pixel definition layer 32 may include the normal pixel definition layer.

According to the display panel provided by the embodiments of the present disclosure, the first pixel definition layer 31 and the second pixel definition layer 32 are arranged in the display panel, and at least one of the first pixel definition layer and the second pixel definition layer includes the light shielding material. The light shielding material can absorb external ambient light and absorb the ambient light reflected by metal structures inside the display panel, thereby reducing the reflectivity of the display panel. Moreover, based on the arrangement shown in FIG. 18 and FIG. 22, the coverage area of the black pixel definition layer in the display panel can be increased, which is conducive to reducing the reflectivity of the display panel.

In addition, as shown in FIG. 18, in some embodiments of the present disclosure, the first opening K12 is formed in the first pixel definition layer 31, the first groove K22 is formed in the second pixel definition layer 32, and the common layer 204 may form the first recessed structure F1 at the first opening K12. In some embodiments of the present disclosure, as shown in FIG. 22, the second groove K12 is formed in the first pixel definition layer 31, the second opening K22 is formed in the second pixel definition layer 32, and the common layer 204 may form the first recessed structure F1 at the second opening K22. As a result, the lateral leakage current path between two adjacent sub-pixels 2 may be prolonged, thereby improving the steal-brightness problem of the sub-pixels 2 and improving the display effect of the display panel.

In addition, as shown in FIG. 18, in some embodiments of the present disclosure, the first groove K22 partially penetrates the second pixel definition layer 32, so that the first opening K12 and the driving function layer 4 can be isolated from each other through the first portion 321 of the second pixel definition layer 32, thereby preventing the common layer 204 located in the first opening K12 and the driving function layer 4 from contacting each other at the first opening K12, and preventing the preparation process of the common layer 204 from affecting the film layers in the driving function layer 4.

In some embodiments of the present disclosure, as shown in FIG. 22, the second groove K12 partially penetrates the first pixel definition layer 31, so that the second opening K22 and the driving function layer 4 can be isolated through the first sub-portion 3111 of the first pixel definition layer 31, thereby preventing the common layer 204 and the driving function layer 4 from contacting each other at the second opening K22, and preventing the preparation process of the common layer 204 from affecting the film layers in the driving function layer 4.

In some embodiments of the present disclosure, as shown in FIG. 18, the angle between a sidewall S11 of the first pixel opening K11 and the plane of the substrate 1 on a side facing away from the first pixel opening K11 is θ11, and the angle between a sidewall S12 of the first opening K12 and the plane of the substrate 1 on a side facing away from the first opening K12 is θ12, where |θ11−θ12|≤5°. Based on such arrangement, the first pixel opening K11 and the first opening K12 may be formed in the same patterning process. In some embodiments of the present disclosure, the first pixel definition layer 31 includes a photosensitive material, and the patterning process includes steps of exposing, developing, and curing the initial film layer for forming the first pixel definition layer 31.

In some embodiments of the present disclosure, as shown in FIG. 18, the angle between a sidewall S21 of the second pixel opening K21 and the plane of the substrate 1 on a side facing away from the second pixel opening K21 is θ21, and the angle is formed between a sidewall S22 of the first groove K22 and the plane of the substrate 1 on a side facing away from the first groove K22 is θ22, where |θ21−θ22|≤5°. Based on such arrangement, the second pixel opening K21 and the first groove K22 may be formed in the same patterning process. In some embodiments of the present disclosure, the second pixel definition layer 32 includes a photosensitive material, and the patterning process includes steps of exposing, developing, and curing the initial film layer for forming the second pixel definition layer 32.

In some embodiments of the present disclosure, as shown in FIG. 22, the angle between a sidewall S11 of the first pixel opening K11 and the plane of the substrate 1 on a side facing away from the first pixel opening K11 is θ11, and the angle between a sidewall S12 of the second groove K12 and the plane of the substrate 1 on a side facing away from the second groove K12 is θ12, where |θ11−θ12|≤5°. Based on such arrangement, the first pixel opening K11 and the second groove K12 may be formed in the same patterning process. In some embodiments of the present disclosure, the first pixel definition layer 31 includes a photosensitive material, and the patterning process includes steps of exposing, developing, and curing the initial film layer for forming the first pixel definition layer 31.

In some embodiments of the present disclosure, as shown in FIG. 22, the angle between a sidewall S21 of the second pixel opening K21 and the plane of the substrate 1 on a side facing away from the second pixel opening K21 is θ21, and the angle is formed between a sidewall S22 of the second opening K22 and the plane of the substrate 1 on a side facing away from the second opening K22 is θ22, where |θ21−θ22|≤5°. Based on such arrangement, the second pixel opening K21 and the second opening K22 may be formed in the same patterning process. In some embodiments of the present disclosure, the second pixel definition layer 32 includes a photosensitive material, and the patterning process includes steps of exposing, developing, and curing the initial film layer for forming the second pixel definition layer 32.

It should be noted that the magnitude relationship between θ11 and θ21 is not limited in the present disclosure, and FIG. 18 and FIG. 22 merely schematically show that θ11 is greater than θ21.

As shown in FIG. 18, the orthographic projection of the first opening K12 on the plane of the substrate 1 is at least partially located within the orthographic projection of the second opening K22 on the plane of the substrate 1. Along the direction perpendicular to the plane of the substrate 1, the angle between a sidewall of the first opening K12 and the plane of the substrate 1 on a side facing away from the first opening K12 is θ12, where 60°<θ12<90°. Based on such arrangement, the sidewall S12 of the first opening K12 may be steeper, which is conducive to increasing the recess degree of the first recessed structure F1 arranged corresponding to the first opening K12, thereby further increasing the lateral leakage current path between two adjacent sub-pixels 2.

In some embodiments of the present disclosure, as shown in FIG. 22, the orthographic projection of the second opening K22 on the plane of the substrate 1 is located within the orthographic projection of the first opening K12 on the plane of the substrate 1. Along the direction perpendicular to the plane of the substrate 1, the angle between a sidewall of the second opening K22 and the plane of the substrate 1 on a side facing away from the second opening K22 is θ22, where 60°<θ22<90°. Based on such arrangement, the sidewall S22 of the second opening K22 may be steeper, which is conducive to increasing the recess degree of the first recessed structure F1 arranged corresponding to the second opening K22, thereby further increasing the lateral leakage current path between two adjacent sub-pixels 2.

In some embodiments of the present disclosure, as shown in FIG. 18, when the first opening K12 penetrates the first pixel definition layer 31 and the first groove K22 partially penetrates the second pixel definition layer 32, the second pixel definition layer 32 includes a first portion 321. The first portion 321 is located in the first opening K12, and the thickness c of the first portion 321 is less than the depth d of the first opening K12. The depth direction of the first opening K12 is perpendicular to the plane of the substrate 1.

Based on such arrangement, a space may be reserved for the arrangement of the first recessed structure F1 of the common layer 204 on the side of the first portion 321 away from the substrate 1, which is beneficial to prolonging the leakage current path between two adjacent sub-pixels 2.

In some embodiments of the present disclosure, as shown in FIG. 18, the orthographic projection of the first opening K12 on the plane of the substrate 1 is at least partially located within the orthographic projection of the first groove K22 on the plane of the substrate 1, and the sidewall S22 of the first groove K22 at least partially overlaps the surface S31 of the first pixel definition layer 31 away from the substrate 1.

In some embodiments of the present disclosure, as shown in FIG. 22, the orthographic projection of the second opening K22 on the plane of the substrate 1 is at least partially located within the orthographic projection of the second groove K12 on the plane of the substrate 1. Along the direction perpendicular to the plane of the substrate 1, the sidewall S12 of the second groove K12 at least partially does not overlap the surface S32 of the second pixel definition layer 32 away from the substrate.

As shown in FIG. 22, the second groove K12 at least partially overlaps the second pixel opening K21 in the direction perpendicular to the plane of the substrate 1, and the overlapping portion of the two is defined as a first overlapping portion K01.

As shown in FIG. 22, in addition to the first sub-pixel definition layer 311 and the second sub-pixel definition layer 312, the first pixel definition layer 31 further includes a third sub-pixel definition layer 313. Along the direction perpendicular to the plane of the substrate 1, the third sub-pixel definition layer 313 at least partially overlaps the first overlapping portion K01.

As shown in FIG. 22, on the side of the third sub-pixel definition layer 313 away from the substrate 1, the common layer 204 forms the second undulating structure F2. As a result, on the basis of arranging the first undulating structure F1, the number of undulating structures in the common layer 204 that are located between two adjacent sub-pixels 2 can be increased, which is conducive to further prolonging the lateral leakage current path of carriers between two adjacent sub-pixels 2, and suppressing the lateral leakage current problem.

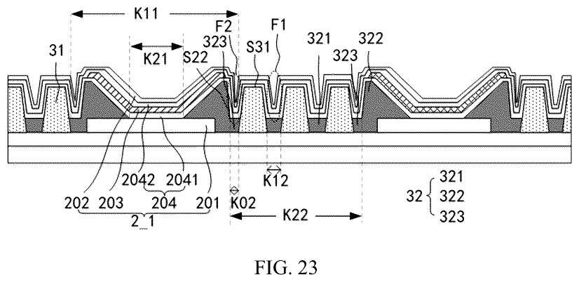

FIG. 22 illustrates how to increase the number of undulating structures in the common layer 204 that are located between two adjacent sub-pixels by taking an example in which the first pixel definition layer 31 includes a second groove K12 partially penetrating the first pixel definition layer 31 and the second pixel definition layer 32 includes a second opening K22 penetrating the second pixel definition layer 32. FIG. 23 is a cross-sectional view of a display panel according to some embodiments of the present disclosure. In some embodiments of the present disclosure, as shown in FIG. 23, the orthographic projection of the first opening K12 on the plane of the substrate 1 is at least partially located within the orthographic projection of the first groove K22 on the plane of the substrate 1. Along the direction perpendicular to the plane of the substrate 1, the sidewall S22 of the first groove K22 at least partially does not overlap the surface S31 of the first pixel definition layer 31 away from the substrate 1.

As shown in FIG. 23, the first groove K22 at least partially overlaps the first pixel opening K11 in the direction perpendicular to the plane of the substrate 1, and the overlapping portion of the two is defined as a second overlapping portion K02.

By comparing FIG. 18 and FIG. 23, it can be seen that in addition to the first portion 321 and the second portion 322 shown in FIG. 18, in FIG. 23, the second pixel definition layer 32 further includes a third portion 323, and along the direction perpendicular to the plane of the substrate 1, the third portion 323 at least partially overlaps the second overlapping portion K02.

As shown in FIG. 22, on the side of the third portion 323 away from the substrate 1, the common layer 204 forms the second undulating structure F2. As a result, on the basis of arranging the first undulating structure F1, the number of undulating structures in the common layer 204 that are located between two adjacent sub-pixels 2 can be increased, thereby further prolonging the lateral leakage current path of carriers between two adjacent sub-pixels 2, and suppressing the lateral leakage current problem.

In some embodiments of the present disclosure, the first pixel definition layer 31 shown in FIG. 22 includes a black pixel definition layer, and the second pixel definition layer 32 shown in FIG. 22 includes a normal pixel definition layer. In addition, the first pixel definition layer 31 shown in FIG. 23 includes a normal pixel definition layer, and the second pixel definition layer 32 shown in FIG. 23 includes a black pixel definition layer. Based on such arrangement, the coverage area of the black pixel definition layer in the display panel can be increased, which is conducive to reducing the reflectivity of the display panel.

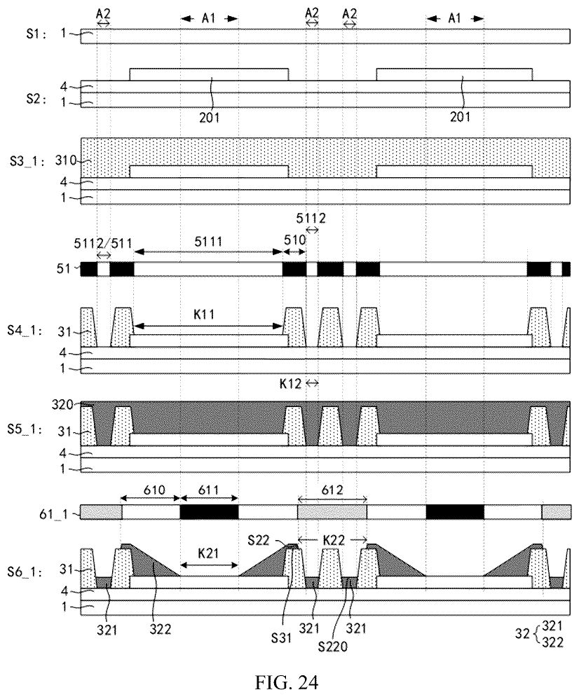

The present disclosure further provides a method for preparing a display panel. FIG. 24 is a schematic flowchart of a method for preparing a display panel according to some embodiments of the present disclosure. As shown in FIG. 24, the method includes as follows.

Step S1: a substrate 1 is provided. In some embodiments of the present disclosure, the substrate 1 includes a first region A1 and a second region A2. The first region A1 may be a light-emitting region of the sub-pixels, which may be understood that the region where the second pixel opening K21 of the display panel shown in FIG. 18 is located. The second region A2 may be the region where the first opening K12 of the display panel shown in FIG. 18 is located. The second region A2 at least partially surrounds the first region A1.

Step S2: a first electrode 201 is formed on a side of the substrate 1. The orthographic projection of the first electrode 201 on the plane of the substrate 1 is at least partially located in the first region A1, that is, the first region A1 at least partially overlap the first electrode 201 in the direction perpendicular to the plane of the substrate 1. The orthographic projection of the first electrode 201 on the plane of the substrate 1 is at least partially offset from the second region A2. For example, the first electrode 201 is arranged to avoid the second region A2.

In some embodiments of the present disclosure, as shown in FIG. 24, the method for preparing the display panel according to the embodiments of the present disclosure further includes a step of forming a driving function layer 4 on a side of the substrate 1. The driving function layer 4 includes a pixel driving circuit for driving the light-emitting element to light up. It should be noted that, the driving function layer 4 is schematically simplified in the embodiments of the present disclosure. In fact, the driving function layer 4 may include a plurality of film layers, and the plurality of film layers include a metal layer, an insulating layer, a semiconductor layer, etc. The specific structure of the driving function layer 4 is not limited in the present disclosure.

Step S3_1: a first initial pixel definition layer 310 is formed on a side of the first electrode 201 away from the substrate 1. The orthographic projection of the first initial pixel definition layer 310 on the plane of the substrate 1 may cover the first region A1 and the second region A2, that is, the orthographic projection of the first initial pixel definition layer 310 on the plane of the substrate 1 may cover the first electrode 201.

Step S4_1: a first pixel opening K11 and a first opening K12 are formed in the first initial pixel definition layer 310 through the first full-grayscale mask plate 51, to obtain a first pixel definition layer 31 including the first pixel opening K11 and the first opening K12.

As shown in FIG. 24, the orthographic projection of the first pixel opening K11 on the plane of the substrate 1 is at least partially located in the first region A1, and the orthographic projection of the first opening K12 on the plane of the substrate 1 is at least partially located in the second region A2. Both the first pixel opening K11 and the first opening K12 penetrate the first pixel definition layer 31. The first pixel opening K11 exposes at least part of the first electrode 201, and the first opening K12 at least partially surrounds the first pixel opening K11.

In some embodiments of the present disclosure, the first initial pixel definition layer 310 may include a positive photosensitive material or a negative photosensitive material. Taking the first initial pixel definition layer 310 including the positive photosensitive material as an example, as shown in FIG. 24, the first full-grayscale mask plate 51 includes a first light-transmitting region and a first non-light-transmitting region 510. In some embodiments of the present disclosure, the first full-grayscale mask plate 51 may include a plurality of first light-transmitting regions, and the plurality of first light-transmitting regions include a first light-transmitting sub-region 5111 and a second light-transmitting sub-region 5112.

When exposing the first initial pixel definition layer 310, the first light-transmitting sub-region 5111 may correspond to the first region A1, and the second light-transmitting sub-region 5112 may correspond to the second region A2.

After the exposure and development processes, a part of the first initial pixel definition layer 310 corresponding to the first light-transmitting sub-region 5111 may be completely removed to form the first pixel opening K11, a part of the first initial pixel definition layer 310 corresponding to the second light-transmitting sub-region 5112 may be completely removed to form the first opening K12, and a part of the first initial pixel definition layer 310 corresponding to the first non-light-transmitting region 510 may be retained to form the non-opening portion of the first pixel definition layer 31.

Step S5_1: a second initial pixel definition layer 320 is formed on a side of the first pixel definition layer 31 away from the substrate 1. As shown in FIG. 24, the second initial pixel definition layer 320 covers the first pixel opening K12 and the first opening K12.

Step S6_1: a second pixel opening K21 and a second opening K22 are formed in the second initial pixel definition layer 320 through the first half-grayscale mask plate 61_1, to obtain a second pixel definition layer 32 including the second pixel opening K21 and the first groove K22. The second pixel opening K21 penetrates the second pixel definition layer 32, to expose at least part of the first electrode 201. The first groove K22 at least partially penetrates the second pixel definition layer 32 at a partial position, and the second opening K22 at least partially surrounds the second pixel opening K21. Along the direction perpendicular to the plane of the substrate 1, the first groove K22 at least partially overlaps the first opening K12, and at least part of the surface of the first groove K22 adjacent to the substrate 1 (S220 as shown in FIG. 24) is located in the first opening K12.

As shown in FIG. 24, the second pixel definition layer 32 includes a first portion 321 and a second portion 322. The first portion 321 is located on a side of a part of the first groove K22 adjacent to the substrate 1, and the second portion 322 is located between the first groove K22 and the second pixel opening K21.

In some embodiments of the present disclosure, the second initial pixel definition layer 320 may include a positive photosensitive material or a negative photosensitive material. Taking the second initial pixel definition layer 320 including the negative photosensitive material as an example, as shown in FIG. 24, the first half-grayscale mask plate 61_1 includes a first full-light-transmitting region 610, a first non-light-transmitting region 611 and a first half-light-transmitting region 612. The light transmittance of the first full-light-transmitting region 610 is greater than the light transmittance of the first half-light-transmitting region 612.

When exposing the second initial pixel definition layer 320, the first non-light-transmitting region 611 may correspond to the first region A1, and the part of the second initial pixel definition layer 320 located in the first region A1 is completely removed to obtain the second pixel opening K21. In addition, the first half-light-transmitting region 612 at least partially corresponds to the second region A2 to partially remove the part of the second initial pixel definition layer 320 located in the second region A2. The removed part corresponds to the first groove K22, and the part of the second initial pixel definition layer 320 retained in the second region A2 corresponds to the first portion 321 of the second pixel definition layer 32. After exposure, development and curing processes, the part of the second initial pixel definition layer 320 corresponding to the first full-light-transmitting region 610 is retained to obtain the second portion 322 of the second pixel definition layer 32.

In some embodiments of the present disclosure, as shown in FIG. 18 and FIG. 24, after the preparation of the first pixel definition layer 31 and the second pixel definition layer 32 shown in FIG. 24, the method for preparing the display panel according to the embodiments of the present disclosure further includes the following steps:

A light-emitting layer 203, a common layer 204, and a second electrode 202 are formed on a side of the second pixel definition layer 32 away from the substrate 1, to obtain a display panel having the structure shown in FIG. 18.

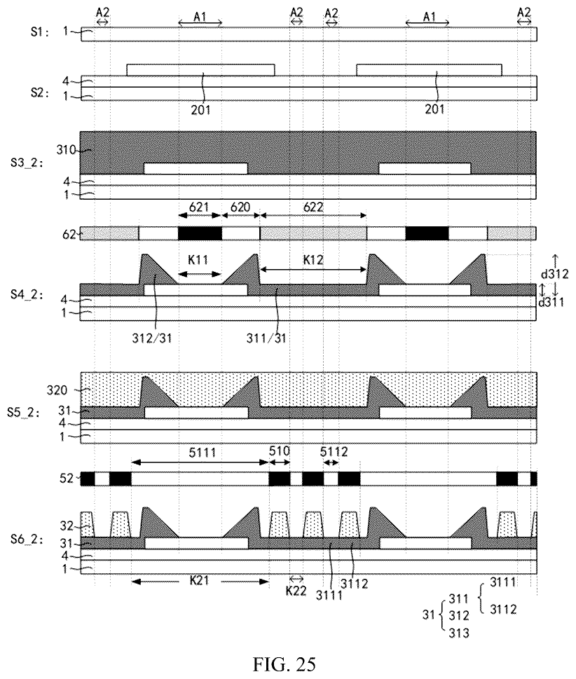

FIG. 25 is a schematic flowchart of a method for preparing a display panel according to some embodiments of the present disclosure. In some embodiments of the present disclosure, as shown in FIG. 25, after the first electrode 201 is prepared on a side of the substrate 1 through steps S1 and S2, the method further includes as follows.

Step S3_2: a first initial pixel definition layer 310 is formed on a side of the first electrode 201 away from the substrate 1.

Step S4_2: a first pixel opening K11 and a second groove K12 are formed in the first initial pixel definition layer 310 through the second half-grayscale mask plate 62, to obtain a first pixel definition layer 31 including the first pixel opening K11 and the second groove K12. The first pixel opening K11 penetrates the first pixel definition layer 31, and the first pixel opening K11 exposes at least part of the first electrode 201. The second groove K12 partially penetrates the first pixel definition layer 31, and the first opening K12 at least partially surrounds the first pixel opening K11.

In some embodiments of the present disclosure, as shown in FIG. 25, the first pixel definition layer 31 obtained through step S4_2 includes a first sub-pixel definition layer 311 and a second sub-pixel definition layer 312. The distance d312 from the surface of the second sub-pixel definition layer 312 away from the substrate 1 to the substrate 1 is greater than the distance d311 from the surface of the first sub-pixel definition layer 311 away from the substrate 1 to the substrate 1. The first sub-pixel definition layer 311 at least partially overlaps the second groove K12 in the direction perpendicular to the plane of the substrate 1. The first sub-pixel definition layer 311 is located on a side of the second groove K12 adjacent to the substrate 1.

In some embodiments of the present disclosure, the first initial pixel definition layer 310 may include a positive photosensitive material or a negative photosensitive material. Taking the first initial pixel definition layer 310 including the negative photosensitive material as an example, as shown in FIG. 25, the second half-grayscale mask plate 62 includes a second full-light-transmitting region 620, a second non-light-transmitting region 621 and a second half-light-transmitting region 622. The light transmittance of the second full-light-transmitting region 620 is greater than the light transmittance of the second half-light-transmitting region 622.

When exposing the first initial pixel definition layer 310, the second non-light-transmitting region 621 may correspond to the first region A1 to completely remove a part of the first initial pixel definition layer 310 located in the first region A1, so as to obtain the first pixel opening K11. In addition, at least part of the second half-light-transmitting region 622 corresponds to the second region A2 to partially remove a part of the first initial pixel definition layer 310 located in the second region A2. The removed part forms the second groove K12, and the part of the first initial pixel definition layer 310 retained in the second region A2 correspondingly forms the first sub-pixel definition layer 311 shown in FIG. 22. A part of the first initial pixel definition layer 310 corresponding to the second full-light-transmitting region 620 is retained to form the second sub-pixel definition layer 312.

Step S5_2: a second initial pixel definition layer 320 is formed on a side of the first pixel definition layer 31 away from the substrate 1.

Step S6_2: a second pixel opening K21 and a second opening K22 are formed in the second initial pixel definition layer 320 through the second full-grayscale mask plate 52 to obtain a second pixel definition layer 32 including the second pixel opening K21 and the second opening K22. The second pixel opening K21 and the second opening K22 both penetrate the second initial pixel definition layer 320. The second pixel opening K21 exposes at least part of the first electrode 201, and the second opening K22 exposes the first sub-portion 3111 of the first sub-pixel definition layer 311 of the first pixel definition layer 31. The second opening K22 at least partially surrounds the second pixel opening K21. Along the direction perpendicular to the plane of the substrate 1, the second opening K22 at least partially overlaps the second groove K12.

In some embodiments of the present disclosure, the second initial pixel definition layer 320 may include a positive photosensitive material or a negative photosensitive material. Taking the second initial pixel definition layer 320 including a positive photosensitive material as an example, as shown in FIG. 25, the second full-grayscale mask plate 52 includes a first light-transmitting region and a first non-light-transmitting region 510. In some embodiments of the present disclosure, the second full-grayscale mask plate 52 may include a plurality of first light-transmitting regions, and the plurality of first light-transmitting regions include a first light-transmitting sub-region 5111 and a second light-transmitting sub-region 5112. When exposing the second initial pixel definition layer 320, the first light-transmitting sub-region 5111 may correspond to the first region A1, and the second light-transmitting sub-region 5112 may correspond to the second region A2.

After the exposure and development processes, a part of the second initial pixel definition layer 320 corresponding to the first light-transmitting region 5111 may be completely removed to form the second pixel opening K21, a part of the second initial pixel definition layer 320 corresponding to the second light-transmitting region 5112 may be completely removed to form the second opening K22, and a part of the second initial pixel definition layer 320 corresponding to the first non-light-transmitting region 510 may be retained to form the non-opening portion of the second pixel definition layer 32.

In some embodiments of the present disclosure, as shown in FIG. 25, the first sub-pixel definition layer 311 includes a first sub-portion 3111 and a second sub-portion 3112. The first sub-portion 3111 at least partially overlaps the second opening K22 in the direction perpendicular to the plane of the substrate 1. The first sub-portion 3111 is located on a side of the second opening K22 adjacent to the substrate 1. The second sub-portion 3112 at least partially does not overlap the second opening K22 in the direction perpendicular to the plane of the substrate 1.

In some embodiments of the present disclosure, as shown in FIG. 22 and FIG. 25, after the preparation of the first pixel definition layer 31 and the second pixel definition layer 32 shown in FIG. 25, the method for preparing the display panel according to the embodiments of the present disclosure further includes the following steps:

A light-emitting layer 203, a common layer 204, and a second electrode 202 are formed on a side of the second pixel definition layer 32 away from the substrate 1, to obtain a display panel having the structure shown in FIG. 22.

In some embodiments of the present disclosure, at least one of the first initial pixel definition layer 310 and the second initial pixel definition layer 320 includes a light-shielding material, so that at least one of the first pixel definition layer 31 and second pixel definition layer 32 that are subsequently formed includes a light-shielding material. The light-shielding material can absorb external ambient light and absorb the ambient light reflected by metal structures inside the display panel, thereby reducing the reflectivity of the display panel.

In some embodiments of the present disclosure, the first initial pixel definition layer 310 shown in FIG. 24 may include a light-transmitting material, and the second initial pixel definition layer 320 shown in FIG. 24 may include a light-shielding material. In addition, the first initial pixel definition layer 310 shown in FIG. 25 includes a light-shielding material, and the second initial pixel definition layer 320 shown in FIG. 25 includes a light-transmitting material. Based on such arrangement, the coverage area of the light-shielding material in the display panel can be increased, which is conducive to reducing the reflectivity of the display panel.

In addition, in some embodiments of the present disclosure, the first pixel definition layer 31 shown in FIG. 24 is provided with a first opening K12 penetrating the first pixel definition layer 31, so that the first opening K12 can prolong the lateral leakage current path between two adjacent sub-pixels 2, thereby improving the steal-brightness problem of the sub-pixels, and improving the display effect of the display panel. In some embodiments of the present disclosure, the second pixel definition layer 32 shown in FIG. 25 is provided with a second opening K22 penetrating the second pixel definition layer 32, so that the second opening K22 can prolong the lateral leakage current path between two adjacent sub-pixels 2, thereby improving the steal-brightness problem of the sub-pixels, and improving the display effect of the display panel.

In addition, as shown in FIG. 24, in some embodiments of the present disclosure, the first groove K22 partially penetrates the second pixel definition layer 32, so that the first opening K12 and the driving function layer 4 can be isolated from each other through the first portion 321 of the second pixel definition layer 32, thereby preventing the common layer 204 located in the first opening K12 and the driving function layer 4 from contacting each other at the first opening K12, and preventing the preparation process of the common layer 204 from affecting the film layers in the driving function layer 4.

In some embodiments of the present disclosure, as shown in FIG. 25, the second groove K12 partially penetrates the first pixel definition layer 31, so that the second opening K22 and the driving function layer 4 can be isolated through the first sub-portion 3111 of the first pixel definition layer 31, thereby preventing the common layer 204 and the driving function layer 4 from contacting each other at the second opening K22, and preventing the preparation process of the common layer 204 from affecting the film layers in the driving function layer 4.

In addition, based on the methods according to the embodiments of the present disclosure, a functional display panel can be realized with only two patterning processes, which is beneficial to simplifying the preparation process of the display panel. The patterning process includes processes such as exposure, development and curing.

In some embodiments of the present disclosure, as shown in FIG. 25, the method of forming the first pixel opening K11 and the second groove K12 in the first initial pixel definition layer 310 through the second half-grayscale mask plate 62 in step S4_2 to obtain the first pixel definition layer 31 including the first pixel opening K11 and the second groove K12 includes as follows.

The first initial pixel definition layer 310 is exposed, developed and cured to completely remove a part of the first initial pixel definition layer 310 located in the first region A1 and partially remove a part of the first initial pixel definition layer 310 located in the second region A2, to obtain the first pixel definition layer 31. The first pixel definition layer 31 includes a first pixel opening K11 at least partially located in the first region A1 and a second groove K12 at least partially located in the second region A2.

In some embodiments of the present disclosure, as shown in FIG. 25, the method of forming the second pixel opening K21 and the second opening K22 in the second initial pixel definition layer 320 through the second full-grayscale mask plate 52 in step S6_2 to obtain the second pixel definition layer 32 including the second pixel opening K21 and the second opening K22 includes as follows.

The second initial pixel definition layer 320 is exposed, developed and cured to completely remove a part of the second initial pixel definition layer 320 located in the first region A1 and a part of the second initial pixel definition layer 320 located in the second region A2, to obtain a second pixel definition layer 32. The second pixel definition layer 32 includes a second pixel opening K21 located in the first region A1 and a first groove K22 located in the second region A2.

In some embodiments of the present disclosure, as shown in FIG. 24, the method of forming the first pixel opening K11 and the first opening K12 in the first initial pixel definition layer 310 through the first full-grayscale mask plate 51 in step S4_1 to obtain the first pixel definition layer 31 including the first pixel opening K11 and the first opening K12 includes as follows.

The first initial pixel definition layer 310 is exposed, developed and cured to completely remove a part of the first initial pixel definition layer 310 located in the first region A1 and a part of the first initial pixel definition layer 310 located in the second region A2, to obtain the first pixel definition layer 31. The first pixel definition layer 31 includes a first pixel opening K11 located in the first region A1 and a first opening K12 located in the second region A2.

In some embodiments of the present disclosure, as shown in FIG. 24, the method for forming the second pixel opening K21 and the first groove K22 in the second initial pixel definition layer 320 through the first half-grayscale mask plate 61_1 in step S6_1 to obtain the second pixel definition layer 32 including the second pixel opening K21 and the first groove K22 includes as follows.

The second initial pixel definition layer 320 is exposed, developed and cured, a part of the second initial pixel definition layer 320 located in the first region A1 is at least completely removed, and a part of the second initial pixel definition layer 320 located in the second region A2 is at least partially removed, to obtain the second pixel definition layer 32. The second pixel definition layer 32 includes a second pixel opening K21 located in the first region A1 and a first groove K22 at least partially located in the second region A2.

When exposing the second initial pixel definition layer 320, in some embodiments of the present disclosure, as shown in FIG. 24, when the first half-grayscale mask plate 61_1 is aligned with the display panel to be exposed, the first half-light-transmitting region 612 may be made to correspond not only to the first opening K12 but also to the partial region that is around the first opening K12 and adjacent to the first opening K12, for example, corresponding to the sidewall of the first opening K12. As shown in FIG. 24, a part of the second initial pixel definition layer 320 located above the sidewall of the first opening K12 and a part of the region located between two adjacent first openings K12 both have smaller thicknesses, so that this part can be completely removed through exposure of the first half-light-transmitting region 612.

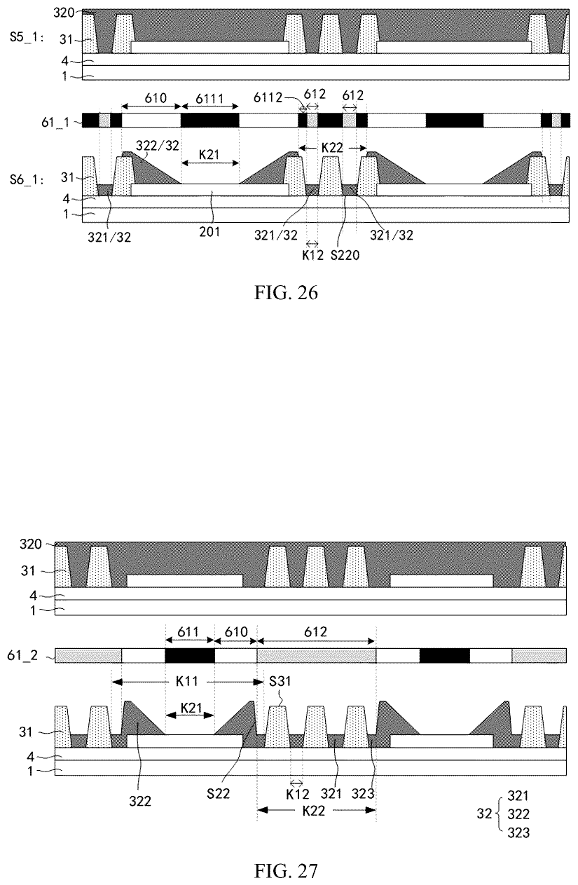

FIG. 26 is a schematic diagram of a method for preparing a second pixel definition layer according to some embodiments of the present disclosure. In some embodiments of the present disclosure, as shown in FIG. 26, the width of the first half-light-transmitting region 612 in the first half-grayscale mask plate 61 may be configured to be smaller. When the first half-grayscale mask plate 61_1 is aligned with the display panel to be exposed, the first half-light-transmitting region 612 may only correspond to the first opening K12.

In some embodiments of the present disclosure, as shown in FIG. 26, the first non-light-transmitting region includes a first non-light-transmitting sub-region 6111 and a second non-light-transmitting sub-region 6112. When exposing the second initial pixel definition layer 320, the first non-light-transmitting sub-region 6111 may correspond to the first region A1 to completely remove a part of the second initial pixel definition layer 320 located in the first region A1, to obtain a second pixel opening K21. In addition, the second non-light-transmitting sub-region 6112 at least corresponds to a sidewall of the first opening K12 to completely remove a part of the second initial pixel definition layer 320 located above the sidewall of the first opening K12 and a part between two adjacent first openings K12. Based on such arrangement, the exposure intensities at different positions may be finely adjusted.

When the first half-grayscale mask plate 61_1 is aligned with the display panel to be exposed, in some embodiments of the present disclosure, as shown in FIG. 24, the first half-light-transmitting region 612 of the first half-grayscale mask plate 61_1 may avoid the first pixel opening K11. Based on such arrangement, after exposure, development and curing processes, along the direction perpendicular to the plane of the substrate 1, the sidewall S22 of the first groove K22 may at least partially overlap the surface S31 of the first pixel definition layer 31 away from the substrate 1, to obtain the display panel having the structure shown in FIG. 18.

FIG. 27 is a schematic diagram of another method for preparing a second pixel definition layer according to some embodiments of the present disclosure. In some embodiments of the present disclosure, as shown in FIG. 27, when the first half-grayscale mask plate 61_2 is aligned with the substrate to be exposed, the first half-light-transmitting region 612 of the first half-grayscale mask plate 61_2 may also correspond to the first pixel opening K11. Based on such arrangement, after exposure, development and curing processes, along the direction perpendicular to the plane of the substrate 1, the sidewall S22 of the first groove K22 at least partially does not overlap the surface S31 of the first pixel definition layer 31 away from the substrate, to obtain the display panel having the structure shown in FIG. 23. As shown in FIG. 27, the position of the second initial pixel definition layer 320 corresponding to the first pixel opening K11 may be partially retained, thereby forming a third portion 323 of the second pixel definition layer 32 having the structure shown in FIG. 23. As shown in FIG. 23, the subsequent common layer 204 may form a second recessed structure F2 on a side of the third portion 323 away from the substrate 1.

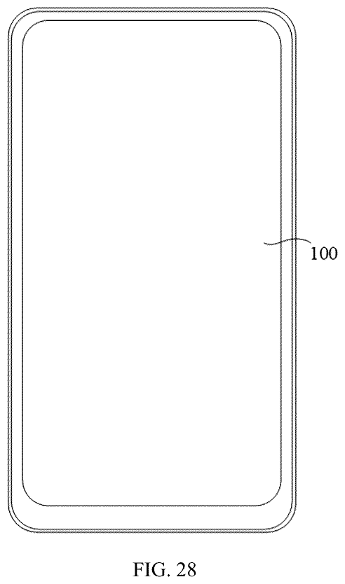

The present disclosure further provides a display apparatus. FIG. 28 is a schematic diagram of a display apparatus according to some embodiments of the present disclosure. As shown in FIG. 28, the display apparatus includes the above display panel. The specific structure of the display panel is described in detail in the above embodiments, and will not be described herein. It is understandable that the display apparatus shown in FIG. 28 is merely illustrative, and the display apparatus may be any device having a display function, such as a mobile phone, a tablet computer, a laptop computer, an electronic paper book, a television, and a smart watch, which is not limited in the present disclosure.

The above description merely illustrates some preferred embodiments of the present disclosure and is not intended to limit the present disclosure, and any modification, equivalent substitution, improvement and the like made within a spirit and a principle of the present disclosure shall fall with the scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate;
a first electrode located on a side of the substrate;
a first pixel definition layer located on a side of the first electrode away from the substrate, wherein the first pixel definition layer comprises a first pixel opening and a first opening, the first pixel opening exposes at least part of the first electrode; and the first opening penetrates the first pixel definition layer, and the first opening at least partially surrounds the first pixel opening;
a second pixel definition layer located on a side of the first pixel definition layer away from the substrate, wherein the second pixel definition layer comprises a second pixel opening and a second opening, the second pixel opening penetrates the second pixel definition layer, and the second pixel opening exposes at least part of the first electrode; the second opening penetrates the second pixel definition layer; the second opening at least partially surrounds the second pixel opening; and the second opening at least partially overlaps the first opening in a direction perpendicular to a plane of the substrate; and
a third pixel definition layer at least partially overlapping the first opening in the direction perpendicular to the plane of the substrate,
wherein at least one of the first pixel definition layer and the second pixel definition layer comprises a light-shielding material.

2. The display panel according to claim 1, wherein at least part of the third pixel definition layer is located in the first opening, and a thickness of the third pixel definition layer is less than a depth of the first opening.

3. The display panel according to claim 2, wherein
a thickness of the third pixel definition layer, c, and a depth of the first opening, d, satisfy: c≤d/2.

4. The display panel according to claim 1, wherein the third pixel definition layer is located on a side of the first pixel definition layer adjacent to the substrate; and
along the direction perpendicular to the plane of the substrate, at least part of the third pixel definition layer does not overlap the first opening, and/or at least part of the third pixel definition layer does not overlap the second opening.

5. The display panel according to claim 1, wherein
an orthographic projection of the first opening on the plane of the substrate is at least partially located within an orthographic projection of the second opening on the plane of the substrate, and a sidewall of the second opening at least partially overlaps a surface of the first pixel definition layer away from the substrate.

6. The display panel according to claim 1, wherein
an orthographic projection of the first opening on the plane of the substrate is at least partially located within an orthographic projection of the second opening on the plane of the substrate, and along the direction perpendicular to the plane of the substrate, a sidewall of the second opening at least partially does not overlap a surface of the first pixel definition layer away from the substrate.

7. The display panel according to claim 1, wherein
an orthographic projection of the first opening on the plane of the substrate is at least partially located within an orthographic projection of the second opening on the plane of the substrate, and along the direction perpendicular to the plane of the substrate, an angle between a sidewall of the first opening and a surface of the substrate is θ12, where 60°<θ12<90°.

8. The display panel according to claim 1, wherein
the third pixel definition layer and the first pixel definition layer are made of a same material.

9. The display panel according to claim 1, wherein
an angle between a sidewall of the first pixel opening and the plane of the substrate on a side facing away from the first pixel opening is θ11, and an angle between a sidewall of the first opening and the plane of the substrate on a side facing away from the first opening is θ12, where |θ11−θ12|≤5°; and
an angle between a sidewall of the second pixel opening and the plane of the substrate on a side facing away from the second pixel opening is θ21, and an angle between a sidewall of the second opening and the plane of the substrate on a side facing away from the second opening is θ22, where |θ21−θ22|≤5°.

10. A method for preparing a display panel, the method comprising:
providing a substrate;
forming a first electrode on a side of the substrate;
forming a first initial pixel definition layer on a side of the first electrode away from the substrate;
forming a first pixel opening and a first opening in the first initial pixel definition layer through a first full-grayscale mask plate to obtain a first pixel definition layer comprising the first pixel opening and the first opening, wherein the first pixel opening exposes at least part of the first electrode, the first opening penetrates the first pixel definition layer, and the first opening at least partially surrounds the first pixel opening;
forming a second initial pixel definition layer on a side of the first pixel definition layer away from the substrate;
forming a second pixel opening and a second opening in the second initial pixel definition layer through a second full-grayscale mask plate, to obtain a second pixel definition layer comprising the second pixel opening and the second opening, wherein the second pixel opening exposes at least part of the first electrode, the second opening penetrates the second pixel definition layer, the second opening at least partially surrounds the second pixel opening, and the second opening at least partially overlaps the first opening in a direction perpendicular to a plane of the substrate; and
forming a third pixel definition layer, wherein the third pixel definition layer at least partially overlaps the first opening along the direction perpendicular to the plane of the substrate,
wherein at least one of the first pixel definition layer and the second pixel definition layer comprises a light-shielding material.

11. The method according to claim 10, wherein said forming the first pixel definition layer comprises:
exposing, developing and curing the first initial pixel definition layer, and completely removing a part of the first initial pixel definition layer located in a first region and a part of the first initial pixel definition layer located in a second region to obtain the first pixel definition layer, wherein the first pixel definition layer comprises the first pixel opening located in the first region and the first opening located in the second region, and wherein the first region at least partially overlap the first electrode in the direction perpendicular to the plane of the substrate, and the second region at least partially surrounds the first region.

12. The method according to claim 10, wherein said forming the second pixel definition layer comprises:
exposing, developing and curing the second initial pixel definition layer, and completely removing a part of the second initial pixel definition layer located in the first region and a part of the second initial pixel definition layer located in the second region to obtain the second pixel definition layer, wherein the second pixel definition layer comprises the second pixel opening located in the first region and the second opening located in the second region, and wherein the first region at least partially overlaps the first electrode in the direction perpendicular to the plane of the substrate, and the second region at least partially surrounds the first region.

13. The method according to claim 10, wherein said forming the third pixel definition layer comprises:
forming a third initial pixel definition layer on a side of the second pixel definition layer away from the substrate, wherein an orthographic projection of the third initial pixel definition layer on the plane of the substrate covers an orthographic projection of the second pixel opening on the plane of the substrate and an orthographic projection of the second opening on the plane of the substrate; and
exposing, developing and curing the third initial pixel definition layer, at least removing a part of the third initial pixel definition layer located in the first region, and at least partially retaining a part of the third initial pixel definition layer located in the second region to obtain the third pixel definition layer at least partially located in the second region, wherein along the direction perpendicular to the plane of the substrate, the first region at least partially overlaps the first electrode, and the second region at least partially overlaps the first opening.

14. The method according to claim 10, wherein said forming the third pixel definition layer comprises:
forming a third initial pixel definition layer on a side of the first pixel definition layer adjacent to the substrate, wherein an orthographic projection of the third initial pixel definition layer on the plane of the substrate covers an orthographic projection of the first pixel opening on the plane of the substrate and an orthographic projection of the first opening on the plane of the substrate; and
exposing, developing and curing the third initial pixel definition layer, and at least removing a part of the third initial pixel definition layer located in the first region to obtain the third pixel definition layer at least partially located in the second region, wherein along the direction perpendicular to the plane of the substrate, the first region at least partially overlaps the first electrode, and the second region at least partially overlaps the first opening.

15. A display apparatus, comprising a display panel, wherein the display panel comprises:
a substrate;
a first electrode located on a side of the substrate;
a first pixel definition layer located on a side of the first electrode away from the substrate, wherein the first pixel definition layer comprises a first pixel opening and a first opening, the first pixel opening exposes at least part of the first electrode; and the first opening penetrates the first pixel definition layer, and the first opening at least partially surrounds the first pixel opening;
a second pixel definition layer located on a side of the first pixel definition layer away from the substrate, wherein the second pixel definition layer comprises a second pixel opening and a second opening, the second pixel opening penetrates the second pixel definition layer, and the second pixel opening exposes at least part of the first electrode; the second opening penetrates the second pixel definition layer; the second opening at least partially surrounds the second pixel opening; and the second opening at least partially overlaps the first opening in a direction perpendicular to a plane of the substrate; and
a third pixel definition layer at least partially overlapping the first opening in the direction perpendicular to the plane of the substrate,
wherein at least one of the first pixel definition layer and the second pixel definition layer comprises a light-shielding material.
